(19) United States
(12) Patent Application Publication
(10) Pub. No.: US 2026/0090446 A1
(43) Pub. Date: Mar. 26, 2026

(54) SEMICONDUCTOR PACKAGE AND MANUFACTURING METHOD THEREOF

(71) Applicant: Samsung Electronics Co., Ltd., Suwon-si (KR)

(72) Inventors: Dawoon Jung, Suwon-si (KR); Haseob Seong, Suwon-si (KR)

(21) Appl. No.: 19/189,510

(22) Filed: Apr. 25, 2025

(30) Foreign Application Priority Data
Sep. 23, 2024 (KR) 10-2024-0128513

(51) Int. Cl. H01L 23/00; H01L 23/48; H01L 25/18; H10B 80/00

(52) U.S. Cl. CPC H10W 72/90; H10W 20/20; H10W 90/00; H10B 80/00; H10W 72/926; H10W 72/932; H10W 72/936; H10W 72/9445; H10W 80/312; H10W 80/327; H10W 90/792

(57) ABSTRACT

According to some embodiments, a semiconductor package includes a base chip, a plurality of memory chips on the base chip, and a bonding metal. The plurality of memory chips includes a first memory chip disposed lowermost among the plurality of memory chips. The bonding metal is disposed on a first outer portion of a top surface of the base chip and a second outer portion of a bottom surface of the first memory chip. The bonding metal is formed by coupling a first metal pattern disposed on the first outer portion to a second metal pattern disposed on the second outer portion.

### CROSS-REFERENCE TO RELATED APPLICATION

This application is based on and claims priority under 35 U.S. C. § 119 to Korean Patent Application No. 10-2024-0128513, filed on Sep. 23, 2024, in the Korean Intellectual Property Office, the disclosure of which is incorporated by reference herein in its entirety.

### FIELD

The application relates to semiconductor packages, and more particularly, to semiconductor packages including a chip stack structure in which semiconductor chips are stacked.

### BACKGROUND

Electronic devices are becoming more compact and lightweight according to the rapid development of the electronics industry and users' demand. As the electronic devices become smaller and lighter, semiconductor packages used therein are also becoming smaller and lighter, and high reliability along with high performance and large capacity are required for the semiconductor packages. To implement small size, weight reduction, high performance, large capacity, and high reliability, research and development of semiconductor chips including through silicon via (TSV) structures and semiconductor packages with a chip stack structure in which the semiconductor chips are stacked are continuously being conducted.

### SUMMARY

Aspects of the present disclosure provide a semiconductor package with reduced or minimized physical damage and improved reliability in a structure in which a plurality of memory chips are stacked.

In addition, the problems to be solved by the technical idea of the inventive concepts disclosed herein are not limited to the above-mentioned problems, and other problems may be clearly understood by those skilled in the art from the description below.

According to some embodiments, a semiconductor package includes a base chip, a plurality of memory chips on the base chip, and a bonding metal. The plurality of memory chips includes a first memory chip disposed lowermost among the plurality of memory chips. The bonding metal is disposed on a first outer portion of a top surface of the base chip and a second outer portion of a bottom surface of the first memory chip. The bonding metal is formed by coupling a first metal pattern disposed on the first outer portion to a second metal pattern disposed on the second outer portion. According to some embodiments, a semiconductor package includes a base chip, a first memory chip stacked on the base chip through hybrid copper bonding (HCB), a plurality of second memory chips stacked on the first memory chip through HCB, and a bonding metal disposed on a first outer portion of a top surface of the base chip and a second outer portion of a bottom surface of the first memory chip, wherein the bonding metal is formed by coupling a first metal pattern disposed on the first outer portion to a second metal pattern disposed on the second outer portion, the top surface of the base chip and the bottom surface of the first memory chip each have a shape of a rectangle, the first metal pattern is disposed at four sides of the rectangle, four vertices of the rectangle, or the four sides and the four vertices, and the second metal pattern is disposed at a position corresponding to the first metal pattern.

According to some embodiments, a semiconductor package includes a package substrate, a first semiconductor device on the package substrate, and at least one second semiconductor device on the package substrate adjacent to the first semiconductor device, wherein the at least one second semiconductor device has a package structure including a base chip, a plurality of memory chips disposed on the base chip, and a bonding metal. The bonding metal is disposed on a first outer portion of a top surface of the base chip and a second outer portion of a bottom surface of a first memory chip disposed lowermost among the plurality of memory chips. The bonding metal is formed by coupling a first metal pattern disposed on the first outer portion to a second metal pattern disposed on the second outer portion.

According to some embodiments, a method of manufacturing a semiconductor package includes: preparing a base chip and a plurality of memory chips; stacking the plurality of memory chips on the base chip; annealing the base chip and the plurality of memory chips; and forming a sealing material sealing the plurality of memory chips on the base chip. The preparing of the base chip and the plurality of memory chips includes: forming a first metal pattern on a first outer portion of a top surface of the base chip; and forming a second metal pattern on a bottom surface of a first memory chip disposed lowermost among the plurality of memory chips.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to some embodiments;

FIGS. 2A and 2B are plan views illustrating a top surface of a base chip and a bottom surface of a first memory chip in the semiconductor package of FIG. 1;

FIGS. 3A and 3B are cross-sectional views illustrating in detail structures of a first metal pattern on the base chip and a second metal pattern on the first memory chip in the semiconductor package of FIG. 1;

FIGS. 4A and 4B are conceptual diagrams and images for explaining a delamination phenomenon occurring in a process of manufacturing a semiconductor package;

FIGS. 5A to 5D are cross-sectional views briefly illustrating a method of manufacturing a semiconductor package, according to an embodiment;

FIGS. 6A to 6D are cross-sectional views illustrating in detail a process of forming a bonding metal by coupling a first metal pattern on a base chip to a second metal pattern on a first memory chip in a process of FIG. 5C;

FIGS. 7A to 7H are cross-sectional views illustrating in detail a process of forming an initial first metal pattern on the base chip in a process of FIG. 5A;

FIGS. 8A to 8E are plan views illustrating a top surface of a base chip and a bottom surface of a first memory chip in a semiconductor package according to some embodiments;

FIGS. 9 to 11 are cross-sectional views of a semiconductor package according to some embodiments;

FIGS. 12A and 12B are a perspective view and a cross-sectional view of a system package according to some embodiments; and

FIGS. 13A to 13D are cross-sectional views of a system package according to some embodiments.

### DETAILED DESCRIPTION OF THE EMBODIMENTS

Hereinafter, embodiments of the inventive concept will be described in detail with reference to the attached drawings. The same reference numerals are used for the same components in the drawings, and redundant descriptions thereof are omitted.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

Further, spatially relative terms, such as “under,” “below,” “lower,” “over,” “upper”, etc., may be used herein for ease of description to describe one element or relationship of structures to another element or structure as illustrated in the drawings.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

The term “exposed” may be used to describe relationships between elements and/or certain intermediate processes in fabricating a completed semiconductor device but may not necessarily require exposure of the particular region, layer, structure or other element in the context of the completed device. An “element A is exposed through an element B” means that at least a portion of the element A is not covered by the element B. However, the thus exposed portion of the element A may be covered by a third element.

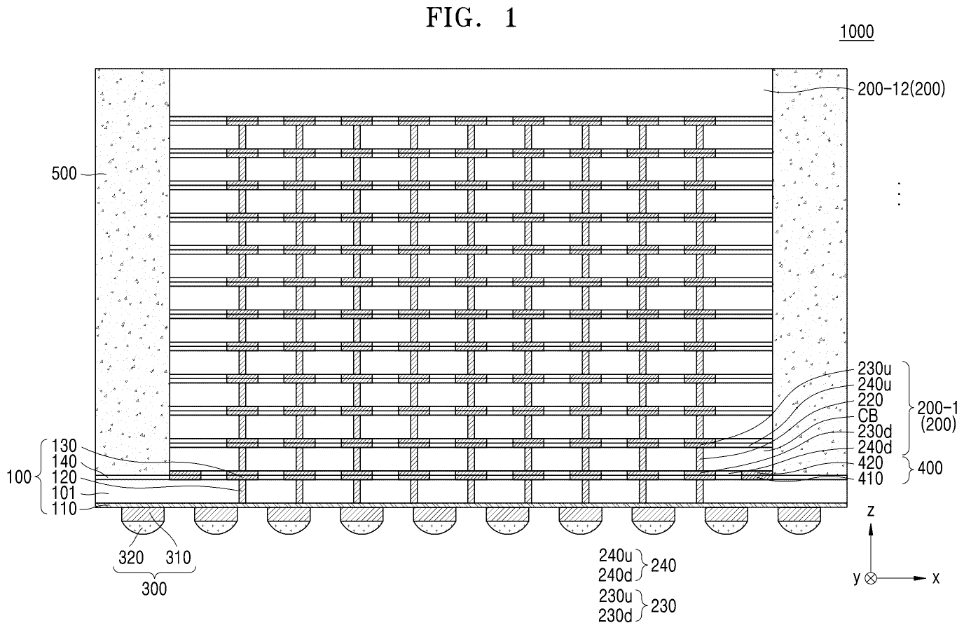

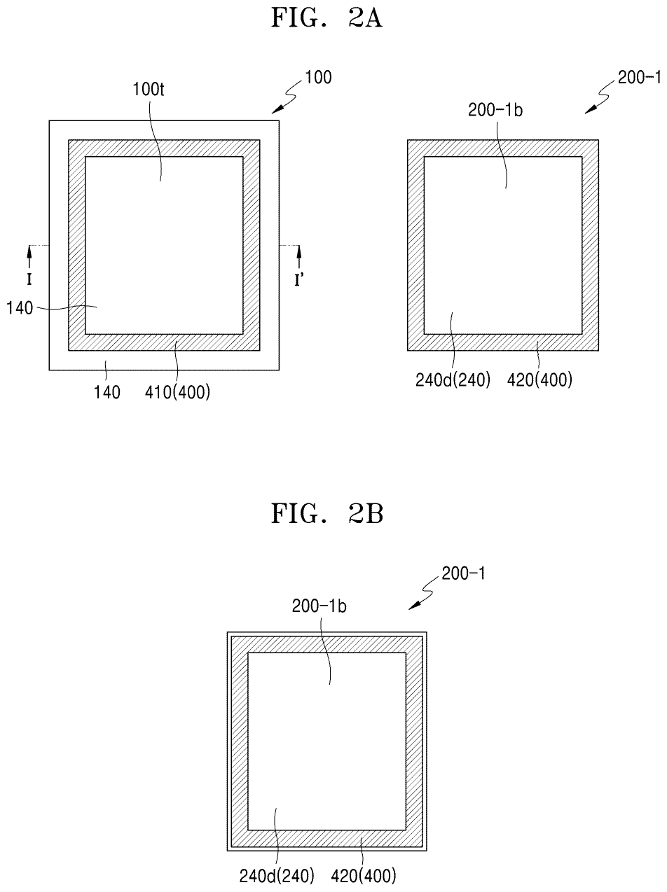

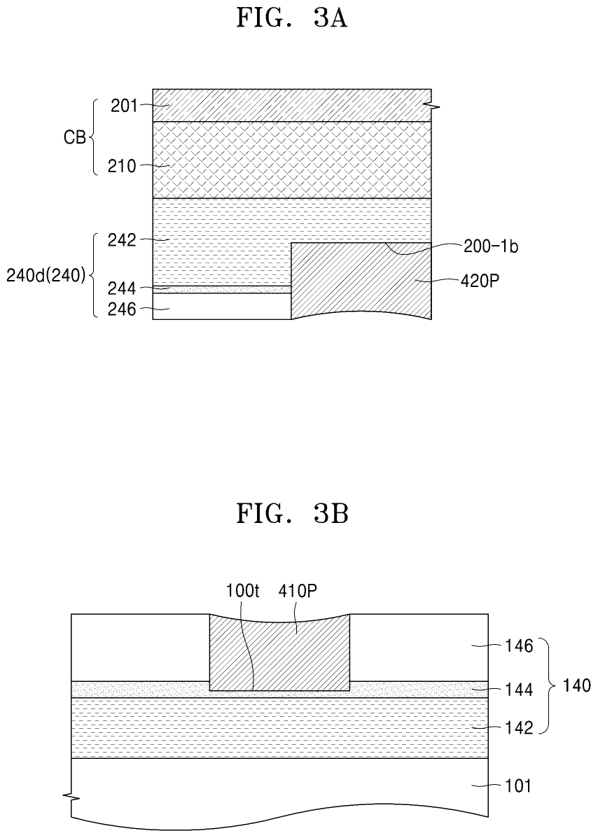

FIG. 1 is a cross-sectional view of a semiconductor package according to some embodiments. FIGS. 2A and 2B are plan views illustrating a top surface of a base chip and a bottom surface of a first memory chip in the semiconductor package of FIG. 1. FIGS. 3A and 3B are cross-sectional views illustrating in detail structures of a first metal pattern of the base chip and a second metal pattern of the first memory chip in the semiconductor package of FIG. 1.

Referring to FIGS. 1 to 3B, a semiconductor package 1000 of the present embodiment may include a base chip 100, a plurality of memory chips 200, an external connection terminal 300, a bonding metal 400, and a sealing material 500.

The base chip 100 may include a substrate body 101, an active layer 110, a through electrode 120, an upper pad 130, and a protective layer 140. As shown in FIG. 1, the base chip 100 may have a size larger than those of the memory chips 200 disposed thereon (i.e., the area of the base chip 100 in a plane orthogonal to the z-axis may be larger than the area of the memory chips in planes orthogonal to the z-axis). However, the size of the base chip 100 is not limited thereto. For example, in some embodiments, the base chip 100 may have substantially the same size as the memory chips 200. Meanwhile, in the semiconductor package 1000 of FIG. 1, the base chip 100 may correspond to a cross-sectional view taken along line I-I′ of the base chip 100 of FIG. 2A.

The substrate body 101 may include, for example, a semiconductor element such as silicon (Si) or germanium (Ge). Also, the substrate body 101 may include a compound semiconductor such as silicon carbide (SiC), gallium arsenide (GaAs), indium arsenide (InAs), or indium phosphide (InP). The substrate body 101 may have a silicon-on-insulator (SOI) structure. For example, the substrate body 101 may include a buried oxide layer BOX. The substrate body 101 may include a structure such as a conductive region, for example, an impurity-doped well, or an impurity-doped source/drain region. The substrate body 101 may include various device isolation structures such as a shallow trench isolation (STI) structure.

The active layer 110 may include an integrated circuit layer and multiple wiring layers on the integrated circuit layer. The integrated circuit layer may include various types of devices. For example, the integrated circuit layer may include a Field Effect Transistor (FET) such as a planar FET or a FinFET, memory such as flash memory, Dynamic Random Access Memory (DRAM), Static Random Access Memory (SRAM), Electrically Erasable Programmable Read-Only Memory (EEPROM), Phase-change Random Access Memory (PRAM), Magnetoresistive Random Access Memory (MRAM), Ferroelectric Random Access Memory (FeRAM), Resistive Random Access Memory (RRAM), etc., logic such as an AND, an OR, a NOT, etc., and various active devices and/or passive devices such as a system Large Scale Integration (LSI), a CMOS Imaging Sensor (CIS), and a Micro-Electro-Mechanical System (MEMS).

The multiple wiring layers may connect at least two devices to each other, connect devices to the conductive region of the substrate body 101, or connect devices to the external connection terminal 300. In addition, the multiple wiring layers may connect the through electrode 120 to the external connection terminal 300. The multiple wiring layers may include, for example, wiring lines and contacts or vias. In the semiconductor package 1000 of the present embodiment, the active layer 110 may be disposed below the through electrode 120. However, in some embodiments, the active layer 110 may be disposed on an upper portion of the through electrode 120. For example, the positional relationship between the active layer 110 and the through electrode 120 may be relative.

In the semiconductor package 1000 of the present embodiment, the base chip 100 may include a plurality of logic devices in the integrated circuit layer of the active layer 110. The base chip 100 may be disposed below the memory chips 200, integrate signals from the memory chips 200 and transmit the signals to the outside, and transmit signals and power from the outside to the memory chips 200. Accordingly, the base chip 100 may be referred to as a buffer chip or an interface chip.

Meanwhile, in some embodiments, the base chip 100 may include a controller that controls signal transmission between the memory chips 200 and an external device. When the base chip 100 includes a controller, the base chip 100 may be referred to as a logic chip, a control chip, etc. In addition, in some embodiments, the base chip 100 may include a Power Management Integrated Circuit (PMIC) that manages power or clock signals. For reference, when the base chip 100 is referred to as a buffer chip, the memory chips 200 may be referred to as core chips.

In the semiconductor package 1000 of the present embodiment, the base chip 100 is not limited to the buffer chip or the logic chip. For example, the base chip 100 may include a plurality of memory devices in the integrated circuit layer of the active layer 110. Accordingly, the base chip 100 may include a memory chip.

The through electrode 120 may penetrate the substrate body 101 and extend from a top surface to a bottom surface of the substrate body 101. In some embodiments, the through electrode 120 may extend into the active layer 110. In the semiconductor package 1000 of the present embodiment, the substrate body 101 may include Si, and accordingly the through electrode 120 may be referred to as a through silicon via (TSV).

The through electrode 120 may have a column shape, and may include a barrier layer on an outer surface and a buried conductive layer therein. The barrier layer may include at least one material selected from Ti, TiN, Ta, TaN, Ru, Co, Mn, WN, Ni, or NiB. The buried conductive layer may include at least one material selected from Cu, a Cu alloy such as CuSn, CuMg, CuNi, CuZn, CuPd, CuAu, CuRe, and CuW, W, a W alloy, Ni, Ru, or Co. Meanwhile, an insulating layer may be disposed between the through electrode 120 and the substrate body 101, or between the through electrode 120 and the active layer 110. The insulating layer may include, for example, an oxide layer, a nitride layer, a carbide layer, a polymer, or a combination thereof.

The upper pad 130 may be disposed on the top surface of the substrate body 101 and connected to the through electrode 120. The upper pad 130 may include at least one of, for example, aluminum (Al), copper (Cu), nickel (Ni), tungsten (W), platinum (Pt), or gold (Au). In the semiconductor package 1000 of the present embodiment, the upper pad 130 may include Cu. However, the material of the upper pad 130 is not limited to Cu.

The protective layer 140 may be disposed on the top surface of the substrate body 101. The protective layer 140 may include, for example, an oxide layer, a nitride layer, a carbide layer, a polymer, or a combination thereof. In the semiconductor package 1000 of the present embodiment, the protective layer 140 may have a multilayer structure. For example, as shown in FIG. 3B, the protective layer 140 may include a first insulating layer 142, a second insulating layer 144, and a third insulating layer 146. For example, the first insulating layer 142 may include a silicon oxide layer, the second insulating layer 144 may include a silicon nitride layer, and the third insulating layer 146 may include a silicon oxide layer. However, the number of layers of the protective layer 140 is not limited to three layers. In addition, the materials of the first, second, and third insulating layers 142, 144, 146 are not limited to the above-described materials.

The upper pad 130 may penetrate at least a part of the protective layer 140. For example, the upper pad 130 may penetrate the protective layer 140 completely or a part of an upper portion of the protective layer 140, and be buried in the protective layer 140. The upper pad 130 on the top surface of the substrate body 101 or inside the protective layer 140 may be connected to the through electrode 120. Although not shown, a lower protective layer may be disposed on a bottom surface of the active layer 110.

The memory chips 200 may be stacked on the base chip 100. In the semiconductor package 1000 of the present embodiment, 12 memory chips 200, for example, first to twelfth memory chips 200-1 to 200-12, may be stacked on the base chip 100. However, the number of memory chips 200 stacked on the base chip 100 is not limited to 12. For example, 2 to 11, or 13 or more memory chips 200 may be stacked on the base chip 100.

For reference, in the semiconductor package 1000 of the present embodiment, the number of memory chips 200 may be 4n (n is a natural number). Accordingly, the semiconductor package 1000 may include the memory chips 200 in a multiple of 4 such as 4, 8, 12, etc. In addition, the four memory chips 200 for each may be tested and operate together with the same stack-ID. For example, when the semiconductor package 1000 includes 12 memory chips 200, first to fourth memory chips 200-1 to 200-4 may have a first stack-ID, fifth to eighth memory chips 200-5 to 200-8 may have a second stack-ID, and ninth to twelfth memory chips 200-9 to 200-12 may have a third stack-ID. However, the semiconductor package 1000 of the present embodiment is not limited to the memory chips 200 in a multiple of 4 and the stack-ID corresponding thereto. For example, the semiconductor package 1000 of the present embodiment may include the memory chips 200 in a multiple of 2 and a stack-ID corresponding thereto, or may include the memory chips 200 in a multiple of 8 and a stack-ID corresponding thereto.

All of the memory chips 200 may have the same size and structure. However, as shown in FIG. 1, a memory chip disposed uppermost among the memory chips 200, for example, the twelfth memory chip 200-12, may not include a through electrode. Also, the twelfth memory chip 200-12 may be thicker than the other memory chips 200. Hereinafter, the first memory chip 200-1 is described for convenience.

The first memory chip 200-1 may include a chip body layer CB, a through electrode 220, a connection pad 230, and a protective layer 240. The chip body layer CB, as shown in FIG. 3A, may include a substrate body 201 and an active layer 210. The substrate body 201 is the same as described with respect to the substrate body 101 of the base chip 100.

The active layer 210 may include a plurality of memory devices. For example, the active layer 210 may include a volatile memory device such as DRAM, SRAM, or a non-volatile memory device such as PRAM, MRAM, FeRAM, or RRAM. For example, in the semiconductor package 1000 of the present embodiment, the first memory chip 200-1 may include DRAM devices in the active layer 210. Accordingly, the first memory chip 200-1 may be a DRAM chip. Also, the first memory chip 200-1 may be a DRAM chip for a high bandwidth memory (HBM). Accordingly, the semiconductor package 1000 of the present embodiment may be an HBM package. However, the semiconductor package 1000 of the present embodiment is not limited to the HBM package.

The through electrode 220 may penetrate the substrate body 201 or may penetrate the substrate body 201 and extend into the active layer 210. For example, when the first memory chip 200-1 is divided into a cell region and a pad region, and the through electrode 220 is formed only in the pad region, the through electrode 220 may penetrate the substrate body 201 and extend into the active layer 210. The other description of the through electrode 220 is the same as described with respect to the through electrode 120 of the base chip 100.

The connection pad 230 may include a lower pad 230d disposed on a bottom surface of the chip body layer CB and an upper pad 230u disposed on a top surface of the chip body layer CB. In a general semiconductor chip, a chip pad may be disposed on a bottom surface of an active layer. Therefore, the lower pad 230d may correspond to a chip pad of the first memory chip 200-1.

The lower pad 230d on the bottom surface of the chip body layer CB may be connected to wirings of multiple wiring layers of the active layer 210. In addition, the lower pad 230d may be connected to the through electrode 220 through wirings of multiple wiring layers. For reference, in FIG. 1, the lower pad 230d is directly connected to the through electrode 220, but this is for convenience of illustration, and actually, multiple wiring layers of the active layer 210 may be between the through electrode 220 and the lower pad 230d.

The upper pad 230u on the top surface of the chip body layer CB may be connected to the through electrode 220. The materials of the lower pad 230d and the upper pad 230u are the same as described with respect to the upper pad 130 of the base chip 100.

The protective layer 240 may include a lower protective layer 240d disposed on the bottom surface of the chip body layer CB and an upper protective layer 240u disposed on the top surface of the chip body layer CB. The protective layer 240 may include, for example, an oxide layer, a nitride layer, a carbide layer, a polymer, or a combination thereof. The upper protective layer 240u is the same as described with respect to the protective layer 140 of the base chip 100.

In the semiconductor package 1000 of the present embodiment, the lower protective layer 240d may have a multilayer structure. For example, as shown in FIG. 3A, the lower protective layer 240d may include a first insulating layer 242, a second insulating layer 244, and a third insulating layer 246. For example, the first insulating layer 242 may include a tetra-Ethly ortho-silicate (TEOS) oxide layer, the second insulating layer 244 may include a silicon nitride layer, and the third insulating layer 246 may include a TEOS oxide layer. In some embodiments, the lower protective layer 240d may further include a fourth insulating layer of silicon carbon nitride on a bottom surface of the third insulating layer 246. However, the number of layers of the lower protective layer 140d is not limited to three or four layers. In addition, the materials of the first, second, and third insulating layers 242, 244, and 246 are not limited to the above-described materials.

The upper pad 230u may penetrate at least a part of the upper protective layer 240u. For example, the upper pad 230u may penetrate the upper protective layer 240u completely or a part of an upper portion of the upper protective layer 240u, and be buried in the upper protective layer 240u. The upper pad 230u on the top surface of the chip body layer CB or inside the upper protective layer 240u may be connected to the through electrode 220.

The lower pad 230d may penetrate at least a part of the lower protective layer 240d. For example, a thick pad metal layer may be disposed in the lower protective layer 240d, and the lower pad 230d may penetrate a part of the lower protective layer 240d and be connected to the pad metal layer. Meanwhile, the pad metal layer may be connected to wirings of multiple wiring layers of the active layer 210. The pad metal layer may include, for example, aluminum (Al). Therefore, the lower pad 230d may be connected to wirings of multiple wiring layers through the pad metal layer, and may also be connected to the through electrode 220 through wirings of multiple wiring layers.

In the semiconductor package 1000 of the present embodiment, the memory chips 200 may be stacked on the base chip 100 or the memory chip 200 directly below the base chip 100 through hybrid copper bonding (HCB). In addition, the memory chips 200 may be stacked on the base chip 100 or the memory chip 200 directly below through thermal compression bonding (TCB). Here, HCB may refer to a combination of pad-to-pad bonding and insulator-to-insulator bonding. On the other hand, pad-to-pad bonding is also called Cu-to-Cu bonding because a pad usually includes Cu.

More specifically, as described above, the upper pad 130 and the protective layer 140 may be located on the top side of the base chip 100 and may form portions of the top surface of the base chip 100. Also, the connection pad 230 and the protective layer 240 may be located on a bottom side and a top side of each of the memory chips 200 and may form portions of the bottom and top surfaces of the memory chips 200. Meanwhile, the upper pad 130 may be penetrate at least a part of the protective layer 140, and the connection pad 230 may penetrate at least a part of the protective layer 240. The protective layers 140 and 240 each may include, for example, an insulating layer such as a silicon oxide layer or a silicon nitride layer.

The upper pad 130 of the base chip 100 may be coupled to the lower pad 230d of the first memory chip 200-1, and the protective layer 140 of the base chip 100 may be coupled to the lower protective layer 240d of the first memory chip 200-1, and thus HCB may be formed between the base chip 100 and the first memory chip 200-1. In addition, the upper pad 230u and the upper protective layer 240u on the top side of the lower memory chip 200 may be coupled to the lower pad 230d and the lower protective layer 240d on the bottom side of the upper memory chip 200 between two adjacent memory chips 200, and thus HCB may be formed.

Meanwhile, in the semiconductor package of some embodiments, the memory chips 200 may not include through electrodes and connection pads. The memory chips 200 may be stacked on the base chip 100 or the lower memory chip 200 through a separate coupling element such as the bonding metal 400. Stacking using the bonding metal 400 may correspond to stacking by a kind of HCB. Meanwhile, because the memory chips 200 do not include through electrodes and connection pads, signal transmission between the memory chips 200 and the base chip 100 may be performed, for example, through wireless communication. Accordingly, each of the memory chips 200 and the base chip 100 may include devices for wireless communication.

The external connection terminal 300 may be disposed on the bottom surface of the base chip 100. The external connection terminal 300 may be connected to wirings of multiple wiring layers of the active layer 110. In addition, the external connection terminal 300 may be connected to the through electrode 120 through wirings of multiple wiring layers. Although not shown, a chip pad may be disposed on the bottom surface of the base chip 100, and the external connection terminal 300 may be disposed on the chip pad.

The external connection terminal 300 may include a pillar 310 and a bump 320. The pillar 310 may have a cylindrical shape, and may include, for example, nickel (Ni), copper (Cu), palladium (Pd), platinum (Pt), gold (Au), or a combination thereof. In some embodiments, the pillar 310 may serve as a chip pad of the base chip 100 and may include Cu. Accordingly, the pillar 310 may be referred to as a bump pad, a Cu-pad, a Cu-pillar, etc. When the pillar 310 serves as a chip pad, a separate chip pad may not be formed on the bottom surface of the base chip 100.

The bump 320 may be disposed on the pillar 310 and may have a hemispherical shape. The bump 320 may include, for example, solder. The solder may include tin (Sn), indium (In), bismuth (Bi), antimony (Sb), copper (Cu), silver (Ag), zinc (Zn), and/or alloys thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc. In some embodiments, the bump 320 may be referred to as a solder, a solder bump, etc. Meanwhile, an intermediate layer may be formed at a contact interface between the pillar 310 and the bump 320. The intermediate layer may include an inter-metallic compound (IMC) formed by reacting metal materials included in the pillar 310 and the bump 320 at a relatively high temperature.

The bonding metal 400 may include a first metal pattern 410 on the base chip 100 and a second metal pattern 420 on the first memory chip 200-1. The first metal pattern 410 and the second metal pattern 420 may have substantially the same shape and may be coupled to each other. In other words, the bonding metal 400 may be formed by coupling the first metal pattern 410 to the second metal pattern 420.

The first metal pattern 410 may be located on the top side of the base chip 100. In particular, the first metal pattern 410 may be disposed on the top surface 100t of the base chip 100. The first metal pattern 410, similar to the upper pad 130, may penetrate at least a part of the protective layer 140 and be buried in the protective layer 140. It will be appreciated that the topography of the top surface 100t may not be even and the portion of the top surface 100t on which the first metal pattern 410 is disposed may not be at the top most height of the base chip (see, for example, FIG. 3B).

As may be seen from FIG. 2A, the first metal pattern 410 may be disposed in the shape of a rectangular ring on the outer portion of the top surface 100t of the base chip 100. In addition, the rectangular ring of the first metal pattern 410 may be spaced apart from four sides or edges of the top surface 100t of the base chip 100 and disposed inside. That is, the outer perimeter of the first metal pattern 410 may be laterally inset from the outer perimeter of the top surface 100t of the base chip 100.

Meanwhile, the first metal pattern 410 may be disposed in a dummy region of the base chip 100. Here, the dummy region may be a concept relative to a main region. The main region is a region where the through electrode 120 and the upper pad 130 connected to the multiple wiring layers of the active layer 110 are disposed, and may be located at the center portion of the base chip 100. On the other hand, the dummy region is a region where the through electrode 120 and the upper pad 130 are not disposed, and may be located at an outer portion of the base chip 100. In some embodiments, a dummy through electrode or a dummy pad that is not connected to the multiple wiring layers may be disposed in the dummy region.

The second metal pattern 420 may be located on the bottom side of the first memory chip 200-1. In particular, the second metal pattern 420 may be disposed on the bottom surface 200-1b of the first memory chip 200-1. The second metal pattern 420, similar to the lower pad 230d, may penetrate at least a part of the lower protective layer 240d and be buried in the lower protective layer 240d. It will be appreciated that the topography of the bottom surface 200-1b may not be even and the portion of the bottom surface 200-1b on which the second metal pattern 420 is disposed may not be at the bottom-most height of the first memory chip 200-1 (see, for example, FIG. 3A).

The second metal pattern 420 may be disposed in a dummy region of the first memory chip 200-1. The first memory chip 200-1 may also include a main region and the dummy region, and the concepts of the main region and the dummy region of the first memory chip 200-1 may be substantially the same as the concepts of the main region and the dummy region of the base chip 100.

As may be seen from FIG. 2A, the second metal pattern 420 may be disposed in the shape of a rectangular ring on the outer portion of the bottom surface 200-1b of the first memory chip 200-1. In addition, the rectangular ring of the second metal pattern 420 may be disposed in contact with four sides of the bottom surface 200-1b of the first memory chip 200-1. In other words, the outer portion of the rectangular ring of the second metal pattern 420 may correspond to the four sides of the bottom surface 200-1b of the first memory chip 200-1. That is, the outer perimeter of the second metal pattern 420 may be coextensive with or aligned with the outer perimeter of the bottom surface 200-1b of the first memory chip 200-1.

However, as shown in FIG. 2B, in some alternative embodiments, the rectangular ring of the second metal pattern 420 may be spaced apart from the four sides or edges of the first memory chip 200-1. That is, the outer perimeter of the second metal pattern 420 may be laterally inset from the outer perimeter of the bottom surface 200-1b of the first memory chip 200-1. However, because the first memory chip 200-1 is smaller than the base chip 100, a distance between the rectangular ring of the second metal pattern 420 and the four sides of the bottom surface 200-1b of the first memory chip 200-1 may be less than a distance between the rectangular ring of the first metal pattern 410 and the four sides of the top surface 100t of the base chip 100.

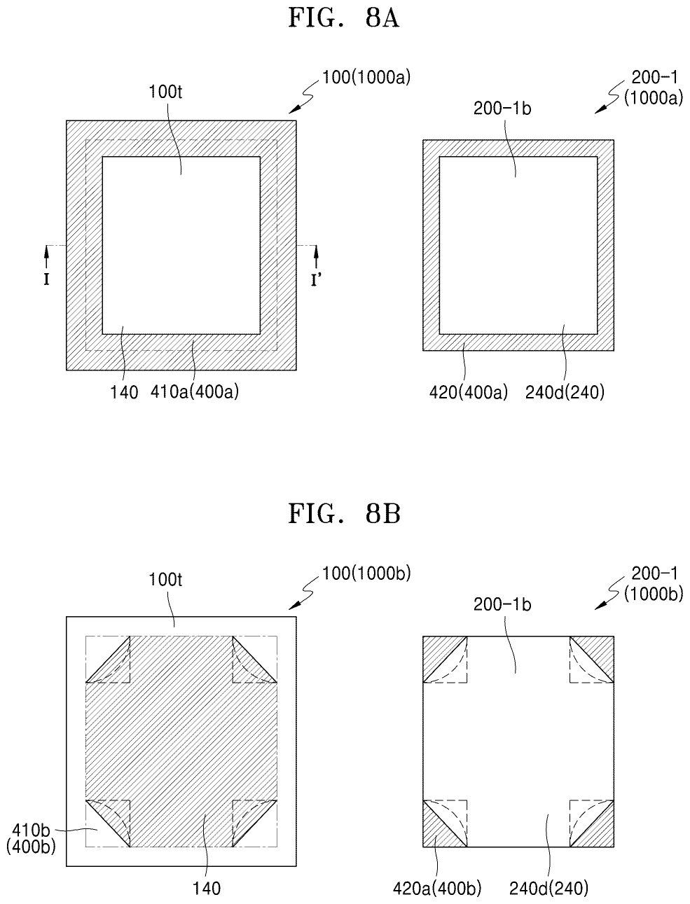

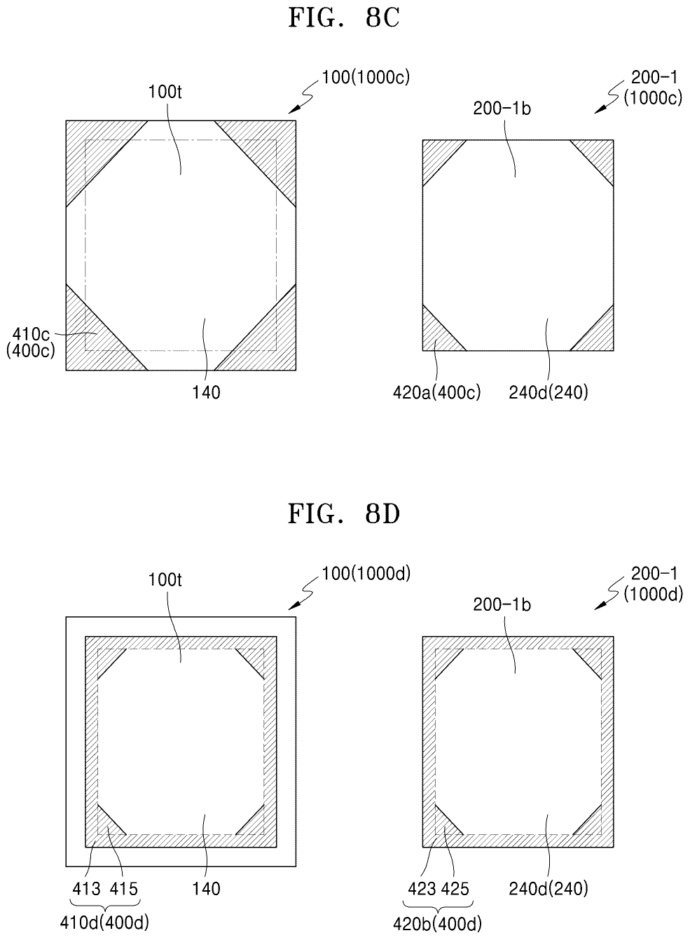

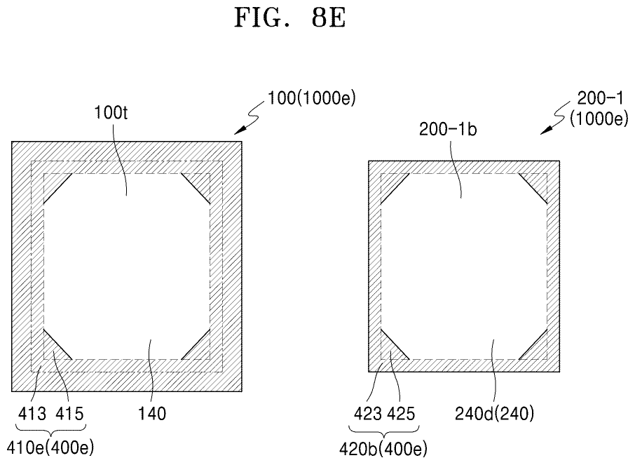

Meanwhile, shapes of the first metal pattern 410 and the second metal pattern 420 are not limited to the shape of the rectangular ring. Various shapes of the first metal pattern 410 and the second metal pattern 420 are described in more detail with reference to FIGS. 8A to 8E.

The first metal pattern 410 and the second metal pattern 420 may include the same metal material. The first metal pattern 410 and the second metal pattern 420 may include at least one of, for example, Al, Cu, Ni, W, Pt, or Au. However, the materials of the first metal pattern 410 and the second metal pattern 420 are not limited to the above-described materials. The first metal pattern 410 and the second metal pattern 420 may be coupled to each other through metal expansion and/or metal diffusion by the same metal materials to form the bonding metal 400.

As may be seen in FIGS. 3A and 3B, an initial first metal pattern 410P and an initial second metal pattern 420P, which are in a separate state before coupling, may have an inwardly concave shape. Such a concave shape may be caused by a dishing phenomenon when the initial first metal pattern 410P and the initial second metal pattern 420P are formed through a chemical mechanical polishing (CMP) process. On the other hand, the concave shape may disappear when the initial first metal pattern 410P and the initial second metal pattern 420P are coupled to each other through an annealing process to form the bonding metal 400.

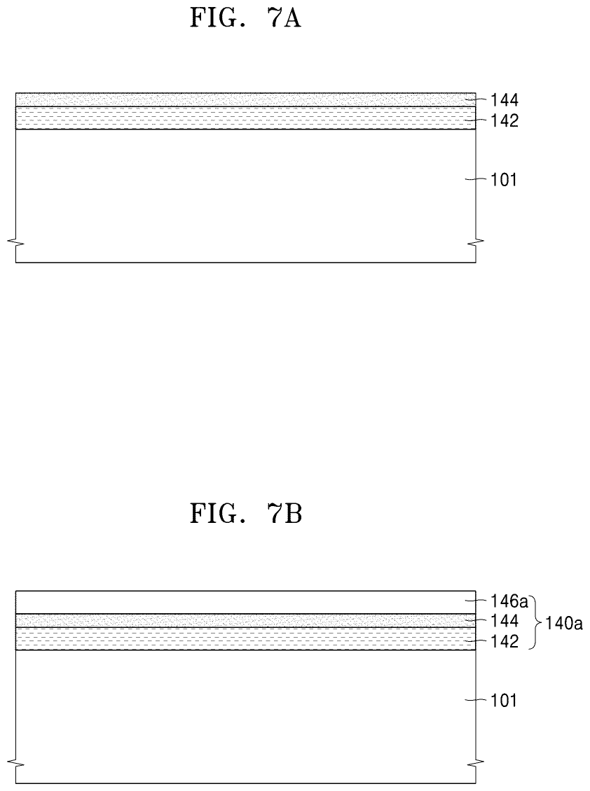

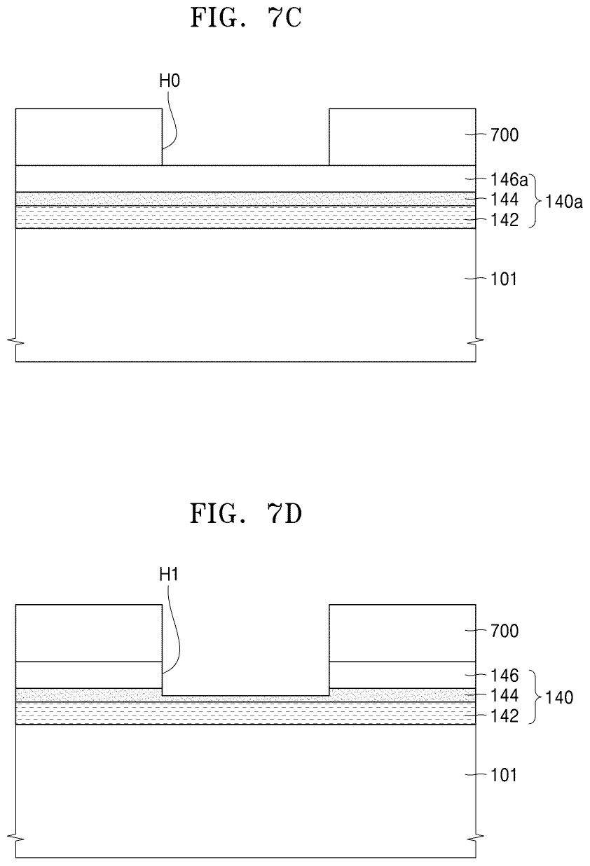

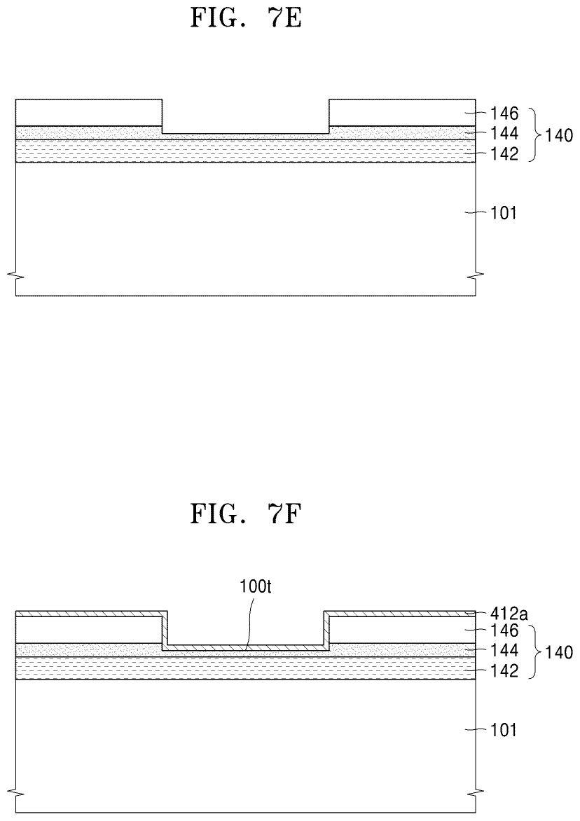

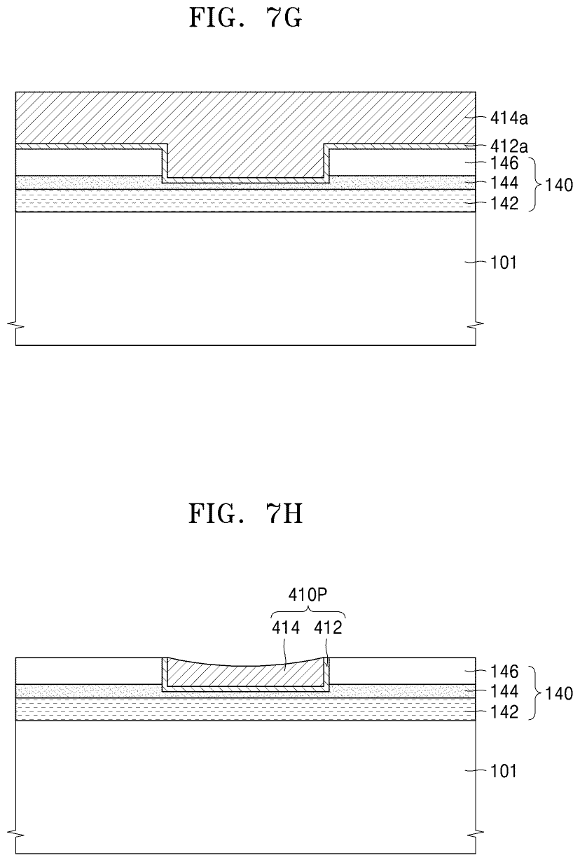

The initial first metal pattern 410P may be formed together with the upper pad 130 of the base chip 100 or may be formed separately from the upper pad 130. In addition, the initial second metal pattern 420P may be formed together with the upper pad 230u of the first memory chip 200-1 or may be formed separately from the upper pad 230u. A method of forming the initial first metal pattern 410P is described in more detail with reference to FIGS. 7A to 7H.

The sealing material 500 may surround side surfaces of the memory chips 200 on the base chip 100. As shown in FIG. 1, the sealing material 500 may not cover a top surface of the uppermost memory chip, for example, the twelfth memory chip 200-12. Accordingly, the top surface of the twelfth memory chip 200-12 may be exposed from the sealing material 500. However, in some embodiments, the sealing material 500 may cover the top surface of the uppermost memory chip, for example, the twelfth memory chip 200-12. The sealing material 500 may include, for example, an epoxy mold compound (EMC). However, the material of the sealing material 500 is not limited to the EMC.

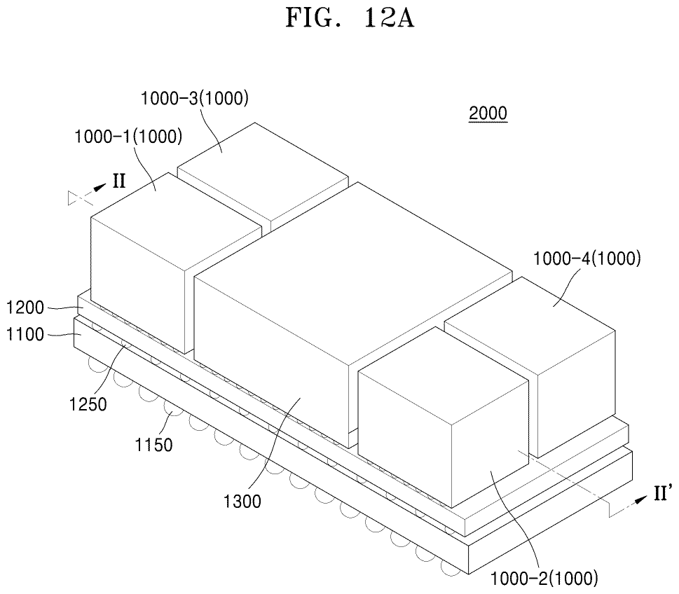

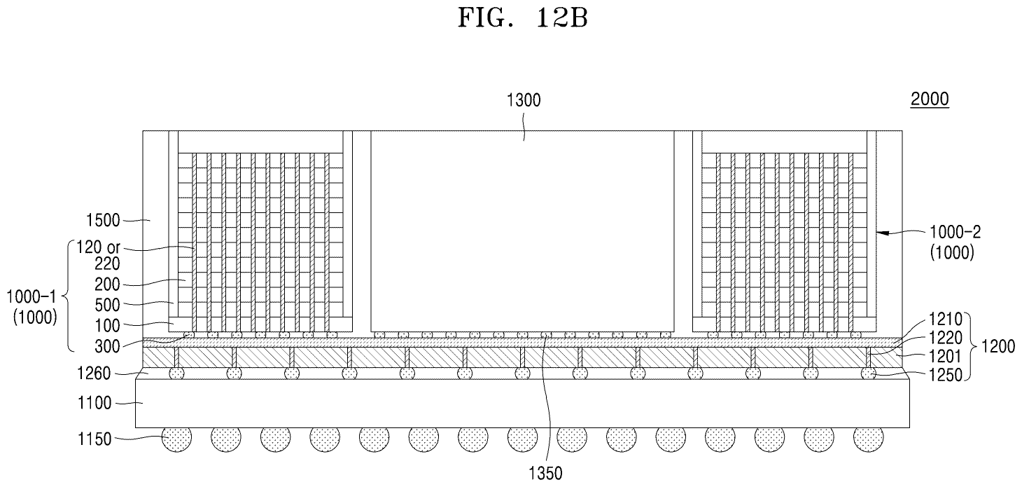

In the semiconductor package 1000 of the present embodiment, the base chip 100 and the first memory chip 200-1 are coupled to each other through the bonding metal 400, thereby effectively suppressing a delamination phenomenon at corners and/or edges of the memory chips 200, particularly the first memory chip 200-1. In addition, the delamination phenomenon of the corners and/or edges of the first memory chip 200-1 is suppressed, thereby preventing physical damage such as cracks in the sealing material 500 surrounding the memory chips 200. As a result, the semiconductor package 1000 of the present embodiment enables Implementation of a semiconductor package with improved reliability owing to reduced or minimized physical damage, and a system package (see 2000 in FIG. 12A) or product including the semiconductor package.

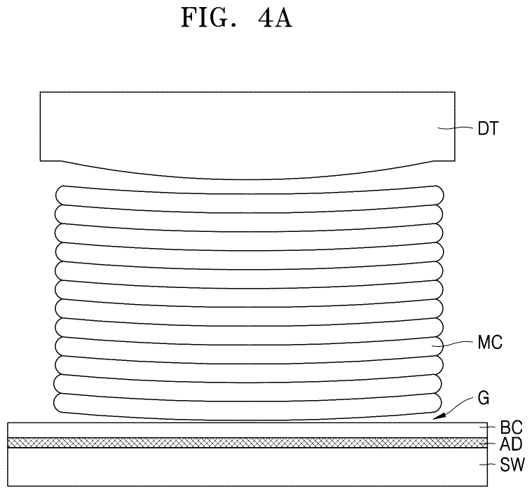

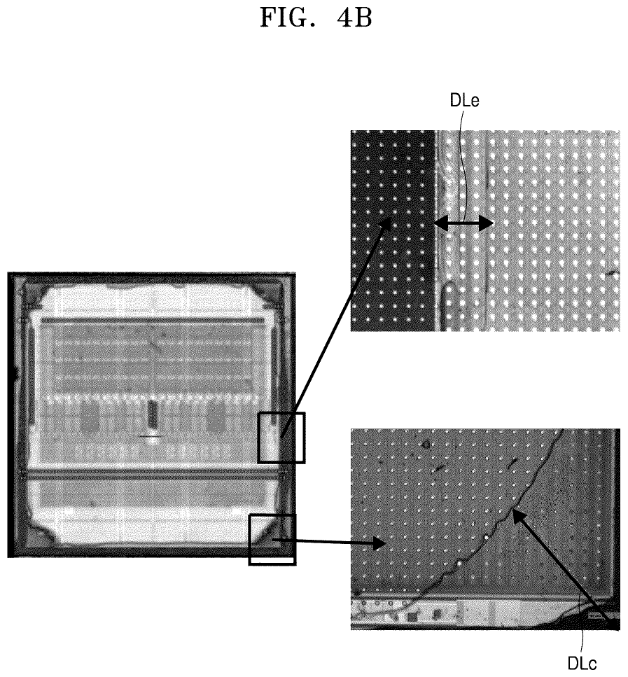

FIGS. 4A and 4B are conceptual diagrams and images for explaining a delamination phenomenon occurring in a process of manufacturing a semiconductor package. FIG. 4A schematically shows a base chip BC and memory chips MC. The descriptions already given with reference to FIGS. 1 to 3B are briefly given or omitted.

Referring to FIGS. 4A and 4B, the plurality of memory chips MC may be stacked on the base chip BC. For reference, in a process of stacking the memory chips MC on the base chip BC, the base chip BC may be in a wafer state. In addition, the base chip BC in the wafer state may be adhered and fixed on a support wafer SW through an adhesive layer AD. FIG. 4A shows only a portion corresponding to one base chip BC for convenience.

In the process of stacking the memory chips MC on the base chip BC, HCB may be performed on each of the memory chips MC. In addition, as shown in FIG. 4A, pressure may be applied downward using a bonding tool DT having a convex central portion. In addition, warpage may occur in the base chip BC and the memory chips MC. Therefore, the delamination phenomenon in which a gap G occurs in corners and/or edges of the memory chips MC, particularly the lowermost memory chip MC, may occur. Here, the corners may mean vertex portions of a bottom surface of the memory chip MC, and the edges may mean sides of the bottom surface of the memory chip MC. On the other hand, the gap G due to the delamination phenomenon may proceed to a sealing material, an underfill, etc. surrounding the memory chips MC later, causing cracks in the sealing material, the underfill, etc., and reducing the reliability of the semiconductor package and a system package or a product including the semiconductor package.

In FIG. 4B, the left image is a scanning acoustic tomography (SAT) image of a top surface of the base chip BC, and the two right images are micrographs showing enlarged portions of solid squares in the left image. In the two right images, a delamination dLe of an edge portion of the base chip BC and a delamination DLc of a core portion may be identified. For reference, small dots in the two right images correspond to upper pads of the base chip BC, and as resins penetrate a portion where delamination has occurred and the pads are discolored by the resins, the pads in the portion where delamination has occurred may be seen more blurred than pads inside.

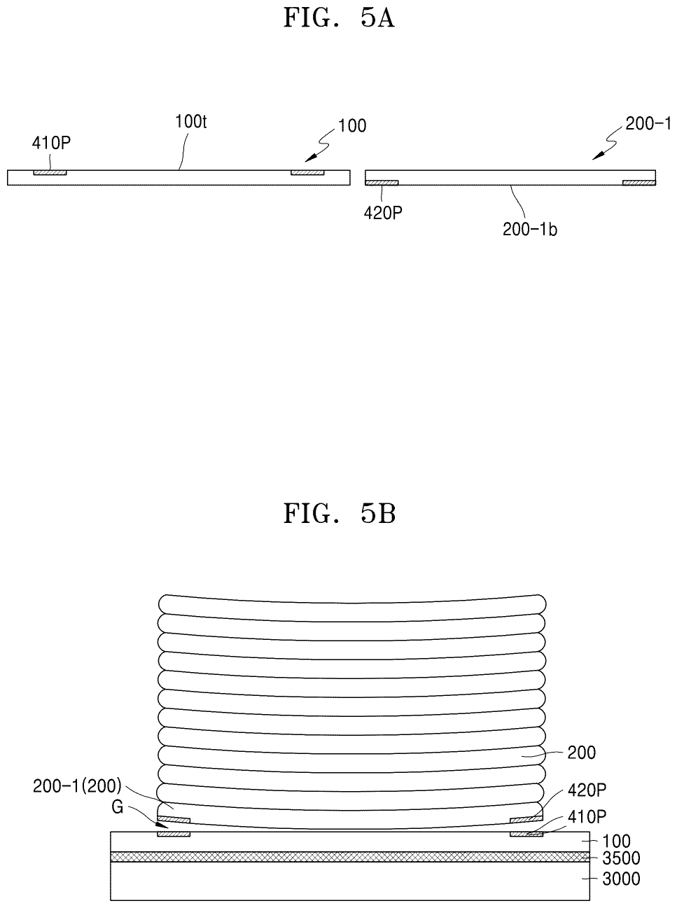

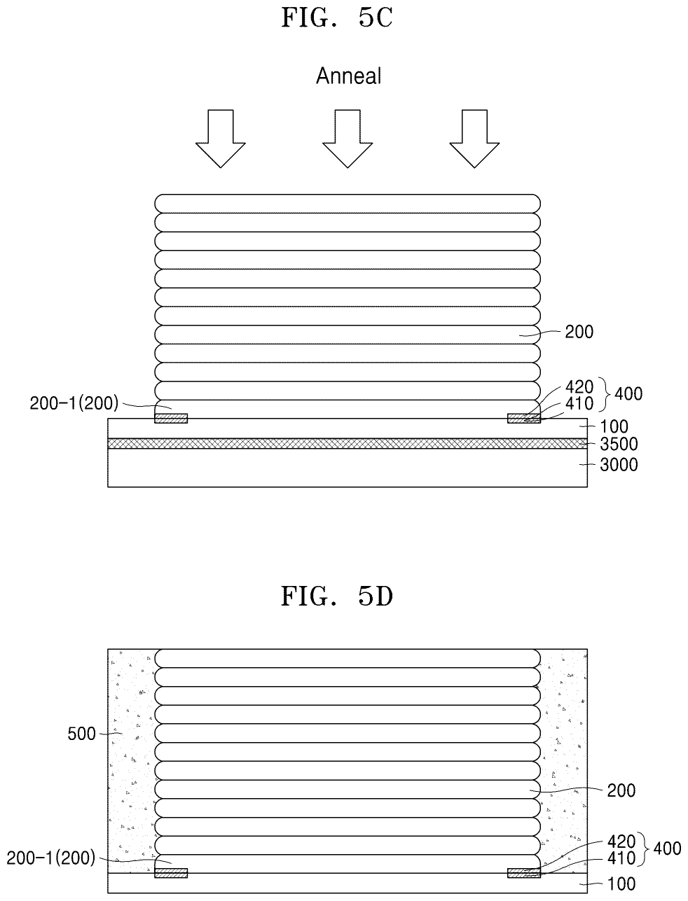

FIGS. 5A to 5D are cross-sectional views briefly illustrating a method of manufacturing a semiconductor package, according to an embodiment. The embodiment is described with reference to FIGS. 1 and 3B together, and the descriptions already given with reference to FIGS. 1 to 4B are briefly given or omitted.

Referring to FIG. 5A, in the method of manufacturing the semiconductor package according to the present embodiment, first, the base chip 100 and the memory chips 200 are prepared. The base chip 100 and the memory chips 200 may be substantially the same as the base chip 100 and the memory chips 200 of the semiconductor package 1000 of FIG. 1. However, the base chip 100 may be in a wafer state rather than in an individual chip state. A wafer may include a plurality of base chips 100.

Meanwhile, the initial first metal pattern 410P may be formed on a top surface 100t of the base chip 100, and the initial second metal pattern 420P may be formed on a bottom surface 200-1b of the first memory chip 200-1 among the memory chips 200. A process of forming the initial first metal pattern 410P is described in more detail with reference to FIGS. 7A to 7H.

Referring to FIG. 5B, thereafter, the plurality of memory chips 200 are stacked on each of the base chips 100 in the wafer state. In a process of stacking the memory chips 200, the base chips 100 in the wafer state may be adhered and fixed on the support wafer 3000 through an adhesive layer 3500. Meanwhile, each of the memory chips 200 may be stacked through HCB, and also through a TCB process, and a bonding tool may be used. Meanwhile, as described above with reference to FIG. 4A, in the process of stacking the memory chips 200, a delamination phenomenon in which the gap G occurs at corners and/or edges of the lowermost first memory chip 200-1 among the memory chips 200 may occur.

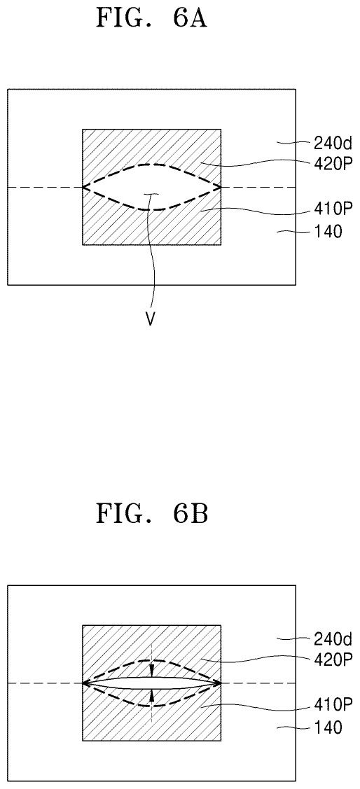

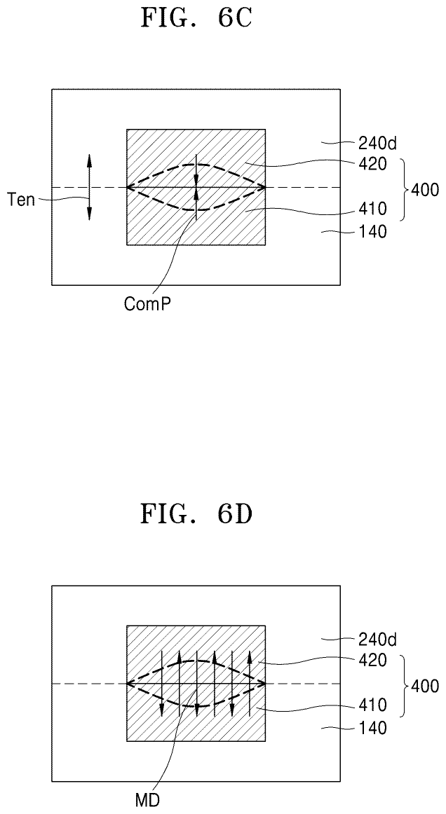

Referring to FIG. 5C, after stacking the memory chips 200, an annealing process is performed. The annealing process may be performed at a temperature of, for example, 200° C. for about 2 hours. The temperature and time of such an annealing process are not limited to the above-described values. Through such an annealing process, the bonding metal 400 may be formed by coupling the first metal pattern 410 of the base chip 100 to the second metal pattern 420 of the first memory chip 200-1. As a result, the gap G may be removed by coupling the base chip 100 to the first memory chip 200-1 through the bonding metal 400. A process of forming the bonding metal 400 by coupling the first metal pattern 410 to the second metal pattern 420 is described in more detail with reference to FIGS. 6A to 6D.

Referring to FIG. 5D, after the bonding metal 400 is formed, the sealing material 500 sealing the memory chips 200 is formed on the base chip 100. The sealing material 500 may be formed at a wafer level. In other words, the sealing material 500 covering all of the memory chips 200 stacked on each of the base chips 100 in the wafer state is formed. Thereafter, the semiconductor package 1000 of FIG. 1 may be completed by individualizing parts of the base chip 100, the memory chips 200 thereon, and the sealing material 500 through a sawing process.

In addition, the external connection terminal 300 may be disposed on the bottom surface of the base chip 100 when preparing the base chip 100 in the wafer state. Accordingly, although not shown in FIGS. 5A to 5D, the external connection terminals 300 of the base chip 100 may be coupled to the adhesive layer 350 on the support wafer 3000, and subsequent processes may proceed. Meanwhile, in some embodiments, the external connection terminal 300 may be disposed on the bottom surface of the base chip 100 in the wafer state after forming the sealing material 500 at the wafer level. After the external connection terminal 300 is disposed, the semiconductor package 1000 of FIG. 1 may be completed by individualizing parts of the base chip 100, the memory chips 200 thereon, and the sealing material 500 through the sawing process.

FIGS. 6A to 6D are cross-sectional views illustrating in detail a process of forming a bonding metal by coupling a first metal pattern of a base chip to a second metal pattern of a first memory chip in a process of FIG. 5C. The descriptions already given with reference to FIGS. 1 to 5D are briefly given or omitted.

Referring to FIG. 6A, when the base chip 100 and the first memory chip 200-1 are coupled to each other through an annealing process, first, the initial first metal pattern 410P of the base chip 100 and the initial second metal pattern 420P of the first memory chip 200-1 are in contact with each other, and the protective layer 140 of the base chip 100 and the lower protective layer 240d of the first memory chip 200-1 are in contact with each other. For example, each of the initial first metal pattern 410P and the initial second metal pattern 420P may include Cu, and each of the protective layer 140 and the lower protective layer 240d may include a silicon oxide layer. However, the materials of the initial first metal pattern 410P and the initial second metal pattern 420P, and the protective layer 140 and the lower protective layer 240d are not limited to the above-described materials.

As shown in FIG. 6A, the initial first metal pattern 410P and the initial second metal pattern 420P have an inwardly concave shape, and accordingly, when coupling starts, a void V may exist between the initial first metal pattern 410P and the initial second metal pattern 420P. In addition, a side surface portion of the initial second metal pattern 420P is exposed as shown in FIG. 3A, but for convenience, in FIGS. 6A to 6D, the side surface portion of the initial second metal pattern 420P is covered by the lower protective layer 240d.

Referring to FIG. 6B, when heat is applied through annealing, the initial first metal pattern 410P and the initial second metal pattern 420P may expand, and the void V may gradually decrease as indicated by dashed arrows. This process is called a metal expansion process, and when the material is Cu, it is called a Cu expansion process.

Referring to FIG. 6C, the initial first metal pattern 410P and the initial second metal pattern 420P continuously expand so that the void V is completely removed, thereby forming the bonding metal 400 including the first metal pattern 410 and the second metal pattern 420. On the other hand, when the bonding metal 400 is formed, compressive stress (indicated in FIG. 6C by the arrow Comp) may act between the first metal pattern 410 and the second metal pattern 420, and tensile stress (indicated in FIG. 6C by the arrow Ten) may act between the protective layer 140 and the lower protective layer 240d. A process of coupling the first metal pattern 410 to the second metal pattern 420 with the compressive stress Com is called bonding by a self-compression process, and when the material is Cu, it is called Cu—Cu bonding by a self-compression process.

Referring to FIG. 6D, after bonding by self-compression, metal diffusion MD in which metal grains move and mix with each other may occur between the first metal pattern 410 and the second metal pattern 420 as indicated by the arrows MD. The first metal pattern 410 and the second metal pattern 420 may be integrated into the bonding metal 400 through the metal diffusion MD. On the other hand, when the material is Cu, it is called Cu diffusion or Cu metal diffusion.

In addition, the coupling process between the first metal pattern 410 and the second metal pattern 420 may be substantially the same as a coupling process between pads in HCB. For example, in a process of stacking the first memory chip 200-1 through HCB, the upper pad 130 and the protective layer 140 of the base chip 100 may be coupled to the lower pad 230d and the lower protective layer 240d of the first memory chip 200-1 through the processes of FIGS. 6A to 6D. In addition, in the two adjacent memory chips 200 in the process of stacking the memory chip 200 through HCB, the upper pad 230u and the upper protective layer 240u on the top surface of the lower memory chip 200 may be coupled to the lower pad 230d and the lower protective layer 240d on the bottom surface of the upper memory chip 200 through the processes of FIGS. 6A to 6D.

FIGS. 7A to 7H are cross-sectional views illustrating in detail a process of forming an initial first metal pattern on a base chip in a process of FIG. 5A. The embodiment is described with reference to FIGS. 1 and 3B together, and the descriptions already given with reference to FIGS. 1 to 6D are briefly given or omitted.

Referring to FIG. 7A, first, a top surface of the through electrode 120 is exposed by performing a CMP process on a top surface of the base chip 100. However, because the portion of FIG. 7A corresponds to a dummy region of the base chip 100, the through electrode 120 is not shown. Meanwhile, the top surface of the base chip 100 may correspond to a backside, which is an inactive surface, and the bottom surface may correspond to a frontside, which is an active surface. In FIG. 7A, the active layer 110 is disposed on a lower portion of the substrate body 101, but is not shown.

The first insulating layer 142 and a second insulating layer 144, which are parts of the protective layer 140, may be disposed on an upper portion of the substrate body 101. The first insulating layer 142 may include, for example, a silicon oxide layer, and the second insulating layer 144 may include, for example, a silicon nitride layer. However, the materials of the first insulating layer 142 and the second insulating layer 144 are not limited to the above-described materials. Meanwhile, the second insulating layer 144 may function as an etching stop layer in the CMP process.

Referring to FIG. 7B, thereafter, a third insulating layer 146a is formed on the second insulating layer 144. The third insulating layer 146a may include, for example, a silicon oxide layer. However, the material of the third insulating layer 146a is not limited to the silicon oxide layer. As the third insulating layer 146a is formed at the uppermost portion of the base chip 100, in some embodiments, only the third insulating layer 146a is referred to as a protective layer, and the first and second lower layers 142 and 144 are referred to as upper insulating layers.

Referring to FIG. 7C, a photoresist (PR) pattern 700 is formed on the third insulating layer 146a through a photo process after the third insulating layer 146a is formed. The PR pattern 700 may include a through hole H0 exposing a top surface of the third insulating layer 146a. A portion exposed through the through hole H0 may correspond to a portion in which the initial first metal pattern 410P is to be formed.

Referring to FIG. 7D, after the PR pattern 700 is formed, an etching process is performed using the PR pattern 700 as a mask. In the etching process, a portion of the third insulating layer 146a exposed through the through hole H0 may be removed, and a first through hole H1 may be formed in the third insulating layer 146a. The second insulating layer 144 may be exposed through a bottom surface of the first through hole H1. Meanwhile, in the etching process, the second insulating layer 144 may act as an etching stop layer. However, in the etching process, at least a part of the second insulating layer 144 may be removed, and accordingly, a recess may be formed in a top surface of the second insulating layer 144, as shown in FIG. 7D.

Referring to FIG. 7E, the PR pattern 700 is removed after the formation of the first through hole H1. The PR pattern 700 may be removed by a strip process or an ashing/strip process.

Referring to FIG. 7F, after the PR pattern 700 is removed, a seed layer 412a is formed by applying a seed metal. The seed layer 412a may include, for example, various metal materials such as Cu, titanium (Ti), tantalum (Ta), titanium nitride (TiN), tantalum nitride (TaN), etc. In the semiconductor package 1000 of the present embodiment, the seed layer 412a may include Ti or Cu.

Referring to FIG. 7G, after the seed layer 412a is formed, a first metal layer 414a is formed through electrode plating using the seed layer 412a. The first metal layer 414a may include, for example, at least one of Al, Cu, Ni, W, Pt, or Au. In the semiconductor package 1000 of the present embodiment, the first metal layer 414a may include Cu. However, the material of the first metal layer 414a is not limited to the above-described materials.

Referring to FIG. 7H, after the first metal layer 414a is formed, a CMP process is executed so that only the first metal layer 414 and the seed layer 412 remain inside the first through hole H1. Parts of the first metal layer 414a and the seed layer 412a on the top surface of the third insulating layer 146 (which forms a portion of the top surface 100t of the base chip 100) are removed. In the CMP process, the parts of the first metal layer 414a and the seed layer 412a on the top surface of the third insulating layer 146 may be removed, and the top surface of the third insulating layer 146 may be exposed. After the CMP process, the first metal layer 414 and the seed layer 412 inside the first through hole H1 may constitute the initial first metal pattern 410P. Due to a dishing phenomenon in the CMP process, a top surface of the initial first metal pattern 410P may have an inwardly concave shape.

Meanwhile, the formation of the initial first metal pattern 410P through the process of FIGS. 7A to 7H may proceed together with the formation of the upper pad 130 in a main region of the base chip 100. However, in some embodiments, the formation of the initial first metal pattern 410P through the process of FIGS. 7A to 7H may proceed separately from the formation of the upper pad 130 in the main region.

In addition, a process of forming the initial second metal pattern 420P on a bottom surface of the first memory chip 200-1 may be substantially the same as the process of forming the initial first metal pattern 410P on a top surface of the base chip 100. However, because the initial second metal pattern 420P is formed on the bottom surface of the first memory chip 200-1, that is, the active surface, the CMP process of exposing the through electrode 220 in FIG. 7A may be omitted. Also, in the etching process, the first through hole H1 may be formed deep to the inside of the first insulating layer 242. This may be due to the formation of the initial second metal pattern 420P together with the lower pad 230d of the main region. However, the initial second metal pattern 420P may be formed separately from the lower pad 230d of the main region, and in such a case, the first through hole H1 may be formed only in the parts of the third insulating layer 246 and the second insulating layer 244.

FIGS. 8A to 8E are plan views illustrating a top surface 100t of a base chip and a bottom surface 200-1b of a first memory chip in a semiconductor package according to some embodiments. The descriptions already given with reference to FIGS. 1 to 7H are briefly given or omitted.

Referring to FIG. 8A, a semiconductor package 1000a of the present embodiment may be different from the semiconductor package 1000 of FIG. 1 in the shape of a bonding metal 400a. Specifically, the semiconductor package 1000a of the present embodiment may include the base chip 100, the plurality of memory chips 200, the external connection terminal 300, the bonding metal 400a, and the sealing material 500. The base chip 100, the plurality of memory chips 200, the external connection terminal 300, and the sealing material 500 are the same as described with respect to the semiconductor package 1000 of FIG. 1. However, as the shape of a first metal pattern 410a of the bonding metal 400a changes, the shape of the protective layer 140 on a top surface 100t of the base chip 100 may change correspondingly.

The bonding metal 400a may include the first metal pattern 410a disposed on the top surface 100t of the base chip 100 and a second metal pattern 420 disposed on a bottom surface 200-1b of the first memory chip 200-1. Unlike the first metal pattern 410 of FIG. 2A, the first metal pattern 410a may cover an outer portion of the top surface 100t of the base chip 100. Specifically, the first metal pattern 410a may expand from a portion (inside of a rectangular dashed line) corresponding to the first metal pattern 410 of FIG. 2A to four sides and four vertices to cover the outer portion of the top surface 100t of the base chip 100. Accordingly, the protective layer 140 may not be disposed on the outer portion of the top surface 100t of the base chip 100. Meanwhile, the shape of the second metal pattern 420 may be substantially the same as that of the second metal pattern 420 of the first memory chip 200-1 of FIG. 2A. Therefore, when the first metal pattern 410a and the second metal pattern 420 are coupled to form the bonding metal 400a, a part (outside of the rectangular dotted line) of the outer portion of the first metal pattern 410a may not be coupled to the second metal pattern 420.

Referring to FIG. 8B, a semiconductor package 1000b of the present embodiment may be different from the semiconductor package 1000 of FIG. 1 in the shape of a bonding metal 400b. Specifically, the semiconductor package 1000b of the present embodiment may include the base chip 100, the plurality of memory chips 200, the external connection terminal 300, the bonding metal 400b, and the sealing material 500. The base chip 100, the plurality of memory chips 200, the external connection terminal 300, and the sealing material 500 are the same as described with respect to the semiconductor package 1000 of FIG. 1. However, as the shapes of a first metal pattern 410b and a second metal pattern 420a of the bonding metal 400b are different from the shapes of the first metal pattern 410 and a second metal pattern 420, the shapes of the protective layer 140 on a top surface 100t of the base chip 100 and the lower protective layer 240d on a bottom surface 200-1b of the first memory chip 200-1 may change correspondingly.

The bonding metal 400b may include the first metal pattern 410b disposed on the top surface 100t of the base chip 100 and the second metal pattern 420a disposed on the bottom surface 200-1b of the first memory chip 200-1. The second metal pattern 420a may be disposed at four vertex parts on the bottom surface 200-1b of the first memory chip 200-1. Specifically, as shown on the right side of FIG. 8B, the second metal pattern 420a may have a triangular shape covering the four vertex parts on the bottom surface 200-1b of the first memory chip 200-1. However, the shape of the second metal pattern 420a is not limited to the triangular shape. As indicated by dotted lines, the second metal pattern 420a may have a square shape or a fan shape covering the four vertex parts.

Meanwhile, the first metal pattern 410b may be disposed on the top surface 100t of the base chip 100, and may have substantially the same shape as the second metal pattern 420a. In addition, the first metal pattern 410b may be disposed at a position corresponding to the second metal pattern 420a. Specifically, as shown on the left side of FIG. 8B, a rectangular portion of a one-point dash line on the top surface 100t of the base chip 100 may correspond to the bottom surface 200-1b of the first memory chip 200-1, and the first metal pattern 410b may have a triangular shape covering four vertex parts of the rectangular portion of the one-point dash line. On the other hand, when the second metal pattern 420a has a square shape or a fan shape, the first metal pattern 410b may also have a square shape or a fan shape, as indicated by dotted lines.

Referring to FIG. 8C, a semiconductor package 1000c of the present embodiment may be different from the semiconductor package 1000b of FIG. 8B in the shape of a bonding metal 400c. Specifically, the semiconductor package 1000c of the present embodiment may include the base chip 100, the plurality of memory chips 200, the external connection terminal 300, the bonding metal 400c, and the sealing material 500. The base chip 100, the plurality of memory chips 200, the external connection terminal 300, and the sealing material 500 are the same as described with respect to the semiconductor package 1000 of FIG. 1. However, as the shapes of a first metal pattern 410c and a second metal pattern 420a of the bonding metal 400c are different from the shapes of the first metal pattern 410 and a second metal pattern 420, the shapes of the protective layer 140 on a top surface 100t of the base chip 100 and the lower protective layer 240d on a bottom surface 200-1b of the first memory chip 200-1 may change correspondingly.

The bonding metal 400c may include the first metal pattern 410c disposed on the top surface 100t of the base chip 100 and the second metal pattern 420a disposed on the bottom surface 200-1b of the first memory chip 200-1. Unlike the first metal pattern 410b of FIG. 8B, the first metal pattern 410c may cover vertex parts of the top surface 100t of the base chip 100. Specifically, the first metal pattern 410c may extend from a portion corresponding to the first metal pattern 410b of FIG. 8B to cover four vertex parts of the top surface 100t of the base chip 100. Accordingly, the protective layer 140 may not be disposed at the four vertex parts of the top surface 100t of the base chip 100. Meanwhile, the first metal pattern 410c has a triangular shape as a whole, but the shape of the first metal pattern 410c is not limited thereto. For example, except for a portion of the first metal pattern 410c coupled to the second metal pattern 420a, the other parts may be changed into various shapes.

Meanwhile, the shape of the second metal pattern 420a may be substantially the same as that of the second metal pattern 420a of the first memory chip 200-1 of FIG. 8B. Therefore, when the first metal pattern 410c and the second metal pattern 420a are coupled to form the bonding metal 400c, a part (outside of a one-point dash line) of an outer portion of the first metal pattern 410c may not be coupled to the second metal pattern 420a.

Referring to FIG. 8D, a semiconductor package 1000d of the present embodiment may be different from the semiconductor package 1000 of FIG. 1 in the shape of a bonding metal 400d. Specifically, the semiconductor package 1000d of the present embodiment may include the base chip 100, the plurality of memory chips 200, the external connection terminal 300, the bonding metal 400d, and the sealing material 500. The base chip 100, the plurality of memory chips 200, the external connection terminal 300, and the sealing material 500 are the same as described with respect to the semiconductor package 1000 of FIG. 1. However, as the shapes of a first metal pattern 410d and a second metal pattern 420b of the bonding metal 400d are different from the shapes of the first metal pattern 410 and a second metal pattern 420, the shapes of the protective layer 140 on a top surface 100t of the base chip 100 and the lower protective layer 240d on a bottom surface 200-1b of the first memory chip 200-1 may change correspondingly.

The bonding metal 400d may include the first metal pattern 410d disposed on the top surface 100t of the base chip 100 and the second metal pattern 420b disposed on the bottom surface 200-1b of the first memory chip 200-1. The second metal pattern 420b may have a composite shape of the second metal pattern 420 of FIG. 2A and the second metal pattern 420a of FIG. 8B. Specifically, as shown on the right side of FIG. 8D, the second metal pattern 420b may include a first portion 423 in the shape of a rectangular ring extending along four sides on the bottom surface 200-1b of the first memory chip 200-1 and a second portion 425 disposed adjacent to four vertices and having a triangular shape. Meanwhile, the shape of the second portion 425 is not limited to the triangular shape. For example, the second portion 425 may have a square shape or a fan shape.

Meanwhile, the first metal pattern 410d may be disposed on the top surface 100t of the base chip 100, and may have substantially the same shape as the second metal pattern 420b. Also, the first metal pattern 410d may be disposed at a position corresponding to the second metal pattern 420b. Specifically, as shown on the left side of FIG. 8d, on the top surface 100t of the base chip 100, the first metal pattern 410d may include a first portion 413 in the shape of a rectangular ring and a second portion 415 having a triangular shape. The first portion 413 of the first metal pattern 410d may have substantially the same shape as the first portion 423 of the second metal pattern 420b, and the second portion 415 of the first metal pattern 410d may have substantially the same shape as the second portion 425 of the second metal pattern 420b. On the other hand, when the second portion 425 of the second metal pattern 420b has a square shape or a fan shape, the second portion 415 of the first metal pattern 410d may also have the square shape or the fan shape.

Referring to FIG. 8E, a semiconductor package 1000e of the present embodiment may be different from the semiconductor package 1000d of FIG. 8D in the shape of a bonding metal 400e. Specifically, the semiconductor package 1000e of the present embodiment may include the base chip 100, the plurality of memory chips 200, the external connection terminal 300, the bonding metal 400e, and the sealing material 500. The base chip 100, the plurality of memory chips 200, the external connection terminal 300, and the sealing material 500 are the same as described with respect to the semiconductor package 1000 of FIG. 1. However, as the shapes of a first metal pattern 410e and a second metal pattern 420b of the bonding metal 400e are different from the shapes of the first metal pattern 410 and a second metal pattern 420, the shapes of the protective layer 140 on a top surface 100t of the base chip 100 and the lower protective layer 240d on a bottom surface 200-1b of the first memory chip 200-1 may change correspondingly.

The bonding metal 400e may include the first metal pattern 410e disposed on the top surface 100t of the base chip 100 and the second metal pattern 420b disposed on the bottom surface 200-1b of the first memory chip 200-1. Unlike the first metal pattern 410d of FIG. 8D, the first metal pattern 410e may entirely cover sides of the top surface 100t of the base chip 100 and outer portions of vertex parts. Specifically, the first metal pattern 410e may expand from a portion corresponding to the first metal pattern 410d of FIG. 8d to four sides and four vertices to cover four sides and four vertex parts of the top surface 100t of the base chip 100. Accordingly, the protective layer 140 may not be disposed on the four sides and the four vertex parts of the top surface 100t of the base chip 100.

Meanwhile, the shape of the second metal pattern 420b may be substantially the same as that of the second metal pattern 420b of the first memory chip 200-1 of FIG. 8D. Therefore, when the first metal pattern 410e and the second metal pattern 420b are coupled to form the bonding metal 400e, a part (outside of a one-point dash line) of the outer portion of the first metal pattern 410e may not be coupled to the second metal pattern 420b.

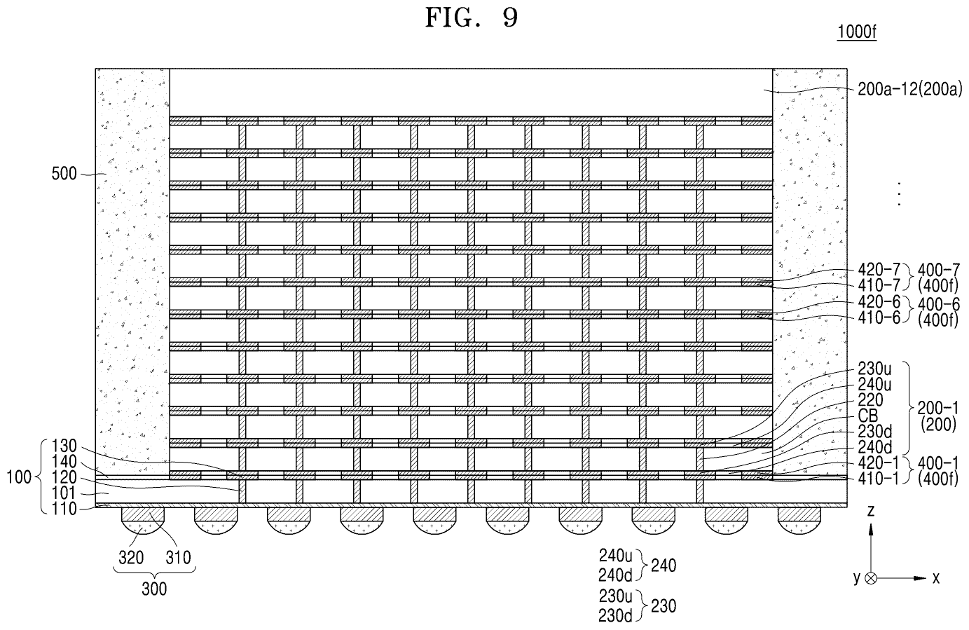

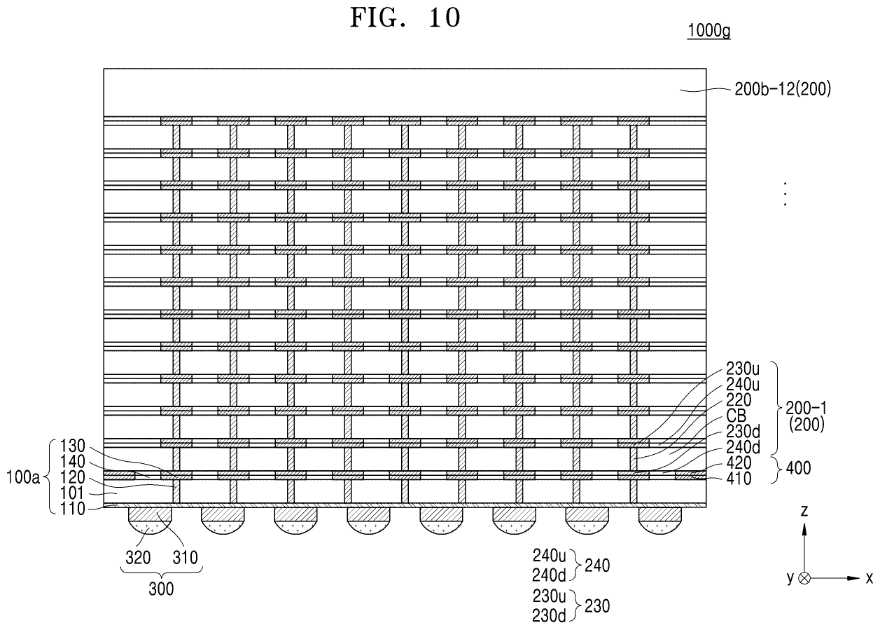

FIGS. 9 to 11 are cross-sectional views of a semiconductor package according to some embodiments. The descriptions already given with reference to FIGS. 1 to 8E are briefly given or omitted.

Referring to FIG. 9, a semiconductor package 1000f of the present embodiment may be different from the semiconductor package 1000 of FIG. 1 in the shape of a bonding metal 400f. Specifically, the semiconductor package 1000f of the present embodiment may include the base chip 100, the plurality of memory chips 200, the external connection terminal 300, the bonding metal 400f, and the sealing material 500. The base chip 100, the plurality of memory chips 200, the external connection terminal 300, and the sealing material 500 are the same as described with respect to the semiconductor package 1000 of FIG. 1. However, as the bonding metal 400f is disposed on all of the memory chips 200, the shape of the protective layer 240 of the memory chips 200 may change correspondingly.

In the semiconductor package 1000f of the present embodiment, the bonding metal 400f may be disposed in all pairs of two adjacent memory chips 200 in the memory chips 200. Specifically, the bonding metal 400f may be disposed on the semiconductor package 1000f in such a manner that a first bonding metal 400-1 is disposed on and between the base chip 100 and the first memory chip 200-1, a sixth bonding metal 400-6 is disposed on and between the fifth memory chip 200-5 and the sixth memory chip 200-6, and a seventh bonding metal 400-7 is disposed on and between the sixth memory chip 200-6 and the seventh memory chip 200-7.

The first bonding metal 400-1 may include a first metal pad 410-1 on a top surface of the base chip 100 and a second metal pad 420-1 on a bottom surface of the first memory chip 200-1. The sixth bonding metal 400-6 may include a first metal pad 410-6 on a top surface of the fifth memory chip 200-5 and a second metal pad 420-6 on a bottom surface of the sixth memory chip 200-6. The seventh bonding metal 400-7 may include a first metal pad 410-7 on a top surface of the sixth memory chip 200-6 and a second metal pad 420-7 on a bottom surface of the seventh memory chip 200-7.

Referring to FIG. 10, a semiconductor package 1000g of the present embodiment may be different from the semiconductor package 1000 of FIG. 1 in the shape of a base chip 100a. In addition, the semiconductor package 1000g of the present embodiment may not include a sealing material. Specifically, the semiconductor package 1000g of the present embodiment may include the base chip 100a, the plurality of memory chips 200, the external connection terminal 300, and the bonding metal 400. The plurality of memory chips 200, the external connection terminal 300, and the bonding metal 400 are the same as described with respect to the semiconductor package 1000 of FIG. 1. However, as the size of the base chip 100a decreases, the first metal pattern 410 of the bonding metal 400 may be in contact with four sides in the form of a rectangular ring on a top surface of the base chip 100a.

In the semiconductor package 1000g according to the present embodiment, the base chip 100a may have substantially the same size as the upper memory chips 200. As described above, because the base chip 100a has the same size as the memory chips 200, a sealing material may be omitted. For reference, such a structure may be implemented by performing a sawing process with the size of the memory chips 200 when individualized through the sawing process after the sealing material is formed.

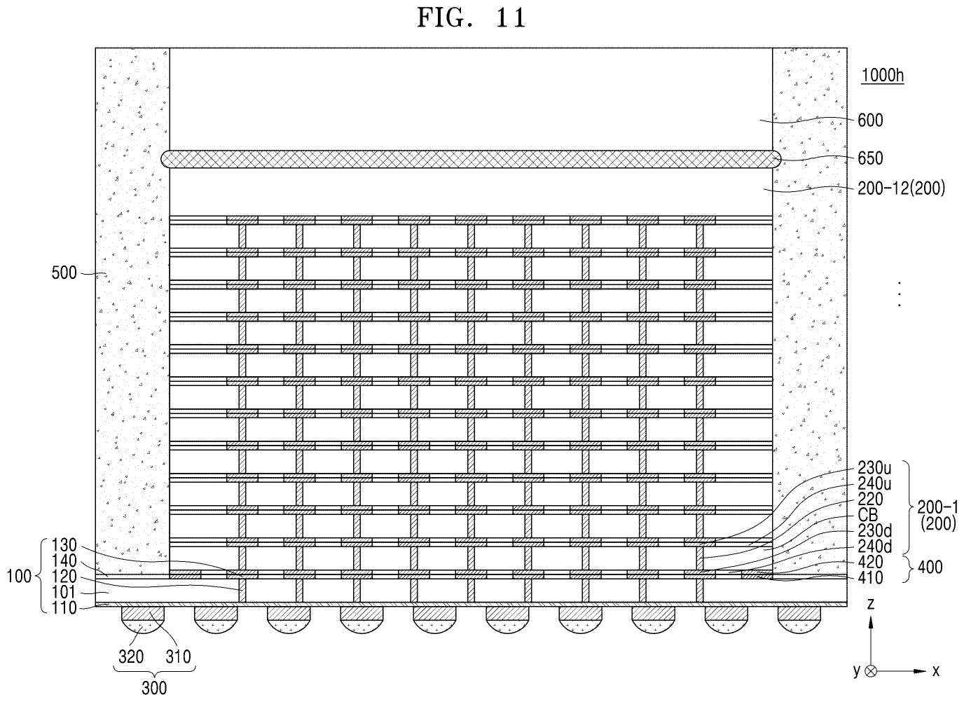

Referring to FIG. 11, a semiconductor package 1000h of the present embodiment may be different from the semiconductor package 1000 of FIG. 1 in that the semiconductor package 1000h further includes a top dummy chip 600. Specifically, the semiconductor package 1000h of the present embodiment may include the base chip 100, the plurality of memory chips 200, the external connection terminal 300, the bonding metal 400, the sealing material 500, and the top dummy chip 600. The base chip 100, the plurality of memory chips 200, the external connection terminal 300, the bonding metal 400, and the sealing material 500 are the same as described with respect to the semiconductor package 1000 of FIG. 1. However, because the top dummy chip 600 is added, the sealing material 500 may be changed to cover a side surface of the top dummy chip 600.

In the semiconductor package 1000h of the present embodiment, the top dummy chip 600 may be stacked on the memory chips 200 through an adhesive layer 650. The top dummy chip 600 may be added to meet the height standard of the semiconductor package 1000h. For example, in the case of an HBM package, the height and area are determined in the JEDEC (Solid State Technology Association) standard, and when the semiconductor package 1000h of the present embodiment is the HBM package, the top dummy chip 600g of an appropriate height is disposed on the memory chips 200, and thus, the height of the semiconductor package 1000h may be adjusted to the JEDEC standard.

Meanwhile, even in the semiconductor packages 1000 and 1000a to 1000g of the previous embodiments, heights of the semiconductor packages 1000 and 1000a to 1000g may be adjusted by adding the top dummy chip 600. In addition, heights of the semiconductor packages 1000 and 1000a to 1000g may be adjusted by adjusting the thickness of the uppermost memory chip 200, for example, the twelfth memory chip 200-12, without the addition of the top dummy chip 600.

The HBM package has been mainly described above, but the semiconductor package of the present embodiment is not limited to the HBM package. For example, the semiconductor package of the present embodiment may be applied to semiconductor packages of any structure in which a semiconductor chip is bonded onto another semiconductor chip or wafer through HCB. In addition, the semiconductor package of the present embodiment is not limited to the stacking of semiconductor chips through HCB of pads, but may be applied to semiconductor packages of all structures in which semiconductor chips are stacked through a separately disposed bonding metal.

FIGS. 12A and 12B are a perspective view and a cross-sectional view of a system package according to some embodiments. FIG. 12B may correspond to a cross-sectional view taken along line II-II′ of FIG. 12A. The embodiment is described with reference to FIG. 1 together, and the descriptions already given with reference to FIGS. 1 to 11 are briefly given or omitted.

Referring to FIGS. 12A and 12B, a system package 2000 of the present embodiment may include the semiconductor package 1000, a package substrate 1100, an interposer 1200, a semiconductor device 1300, and an external sealing material 1500.

As shown in FIG. 12A, the semiconductor package 1000 may include first to fourth semiconductor packages 1000-1 to 1000-4. For example, two semiconductor packages 1000 for each may be disposed on the interposer 1200 on both sides of the semiconductor device 1300. However, in the system package 2000 of the present embodiment, the number of semiconductor packages 1000 is not limited to 4. For example, one to three or five or more semiconductor packages 1000 may be disposed on the interposer 1200.

The semiconductor package 1000 may be, for example, the semiconductor package 1000 of FIG. 1. Accordingly, the semiconductor package 1000 may include the base chip 100, the memory chips 200, the external connection terminal 300, the bonding metal 400, and the sealing material 500. In addition, the bonding metal 400 may include the first metal pattern 410 of the base chip 100 and the second metal pattern 420 of the first memory chip 200-1. Meanwhile, in FIG. 12B, the semiconductor package 1000 is reduced, and accordingly, for convenience, the bonding metal 400 is not shown.

In the system package 2000 of the present embodiment, the semiconductor package 1000 may be an HBM package. Accordingly, the base chip 100 of the semiconductor package 1000 may be a buffer chip, and each of the memory chips 200 may be a DRAM chip. However, the semiconductor package 1000 is not limited to the HBM package. In addition, the semiconductor package 1000 is not limited to the semiconductor package 1000 of FIG. 1. For example, instead of the semiconductor package 1000 of FIG. 1, the semiconductor packages 1000a to 1000h of FIGS. 8A to 11 may be applied to the system package 2000.

The package substrate 1100 is a support substrate, and the interposer 1200, the semiconductor package 1000, and the semiconductor device 1300 may be stacked on the package substrate 1100. The package substrate 1100 may include at least one layer of wiring line therein. When wiring lines are formed in multiple layers, wiring lines of other layers may be connected to each other through vertical vias. The package substrate 1100 may be formed in, for example, a ceramic substrate, a PCB, an organic substrate, an interposer substrate, etc. A first connection terminal 1150 may be disposed on a bottom surface of the package substrate 1100. The system package 2000 may be stacked on an external system substrate or a main board through the first connection terminal 1150.

The interposer 1200 may include an interposer substrate 1201, a wiring layer 1210, a through electrode 1220, and a second connection terminal 1250. The semiconductor package 1000 and the semiconductor device 1300 may be mounted on the package substrate 1100 via the interposer 1200. The interposer 1200 may connect the semiconductor package 1000 and the semiconductor device 1300 to each other. Also, the interposer 1200 may connect the semiconductor package 1000 and the semiconductor device 1300 to the package substrate 1100.

The interposer substrate 1201 may include, for example, Si. Accordingly, the interposer 1200 may be a Si-interposer. The through electrode 1220 may extend through the interposer substrate 1201. Because the interposer substrate 1201 includes silicon, the through electrode 1220 may correspond to a TSV. The through electrode 1220 may extend to the wiring layer 1210 and be connected to the wiring lines of the wiring layer 1210. According to some embodiments, the interposer 1200 may include only a wiring layer therein and may not include a through electrode. The wiring layer 1210 may be disposed on a top surface or a bottom surface of the interposer substrate 1201. For example, the positional relationship between the wiring layer 1210 and the through electrode 1220 may be relative. A pad on a top surface of the interposer 1200 may be connected to the through electrode 1220 through the wiring layer 1210.

The second connection terminal 1250 may be disposed on a bottom surface of the interposer 1200 and connected to the through electrode 1220. The interposer 1200 may be stacked on the package substrate 1100 through the second connection terminal 1250. The second connection terminal 1250 may be connected to the pad on the top surface of the interposer 1200 through the through electrode 1220 and the wiring lines of the wiring layer 1210.

In the system package 2000 of the present embodiment, the interposer 1200 may be used for the purpose of converting an electrical signal or transmitting an electrical signal between the semiconductor package 1000 and the semiconductor device 1300. Accordingly, the interposer 1200 may not include devices such as an active device or a passive device. However, in some embodiments, the interposer 1200 may include devices for controlling signal transmission. Meanwhile, an underfill 1260 may be filled between the interposer 1200 and the package substrate 1100 and between the second connection terminals 1250. In some embodiments, the underfill 1260 may be replaced with an adhesive layer or an adhesive film.

The semiconductor device 1300 may be stacked on a central portion of the interposer 1200 through a third connection terminal 1350. The semiconductor device 1300 may have a chip or package structure. In the system package 2000 of the present embodiment, the semiconductor device 1300 may have a chip structure. For example, the semiconductor device 1300 may include a logic chip. The semiconductor device 1300 may include a plurality of logic devices therein. The logic devices may include, for example, AND, NAND, OR, NOR, exclusive OR (XOR), exclusive NOR (XNOR), inverter (INV), adder (ADD), delay (DLY), filter (FIL), multiplexer (MXT/MXIT), OR/AND/INVERTER (OAI), AND/OR (AO), AND/OR/INVERTER (AOI), D flip-flop, reset flip-flop, master-slaver flip-flop, latch, counter, or buffer devices. The logic devices may perform various signal processes such as analog signal processing, analog-to-digital (A/D) conversion, and control. The semiconductor device 1300 may be referred to as a Central Processing Unit (CPU) chip, a System On Glass (SOG) chip, a Micro-Processor Unit (MPU) chip, a Graphic Processing Unit (GPU) chip, a Natural Processing Unit (NPU) chip, an Application Processor (AP) chip, or a control chip, according to its function.

In the system package 2000 of the present embodiment, the semiconductor device 1300 may have a chip structure, but may have a system on chip (SoC) structure or a chiplet structure. The SoC structure may have a structure in which several systems are integrated into one chip. Accordingly, the semiconductor device 1300 of the SoC structure may solve a computational function, data stage, and A/D signal conversion within one chip. On the other hand, the chiplet structure may have a structure in which a logic chip is divided into separate chips for each function and the chips are connected to each other. The semiconductor device 1300 of the chiplet structure may overcome the performance limit of a single chip.

The external sealing material 1500 may cover and seal the semiconductor device 1300 and the semiconductor package 1000 on the interposer 1200. As shown in FIG. 12B, the external sealing material 1500 may not cover the top surfaces of the semiconductor device 1300 and the semiconductor package 1000. However, in some embodiments, the external sealing material 1500 may cover the top surface of at least one of the semiconductor device 1300 and the semiconductor package 1000. On the other hand, although not shown, the system package 2000 of the present embodiment may further include a second external sealing material that covers and seals the interposer 1200 and the external sealing material 1500 on the package substrate 1100.

For reference, the structure of the system package 2000 of the present embodiment is called a 2.5D package structure, and the 2.5D package structure may be a relative concept of a 3D package structure in which all semiconductor chips are stacked together and there is no interposer. Both the 2.5D package structure and the 3D package structure may be included in a system in package (SIP) structure. In addition, the system package 2000 of the present embodiment is also a semiconductor package but is referred to as a system package so as to be terminologically distinguished from the semiconductor package 1000, which is a component.

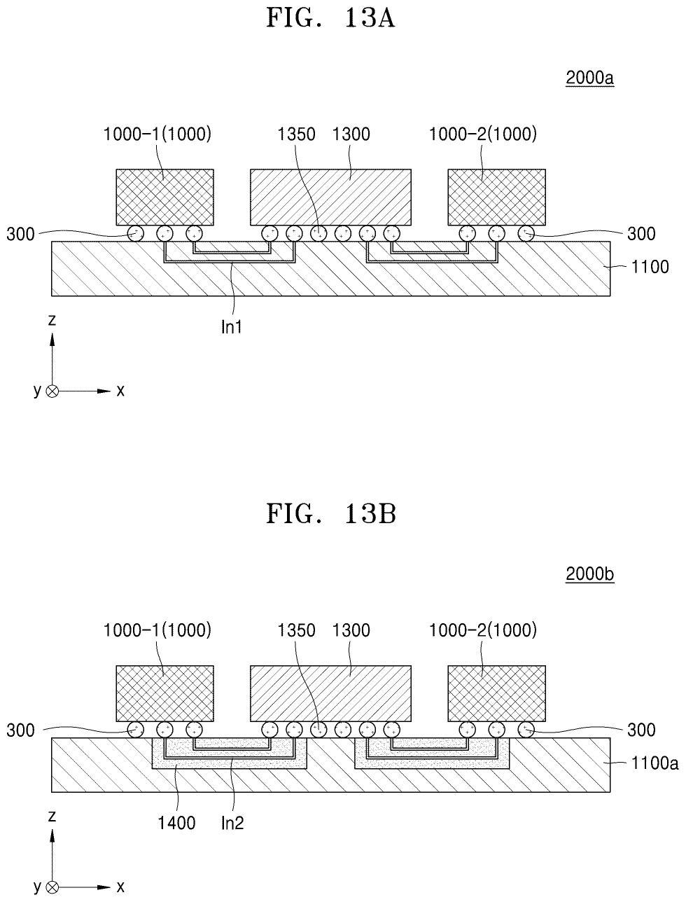

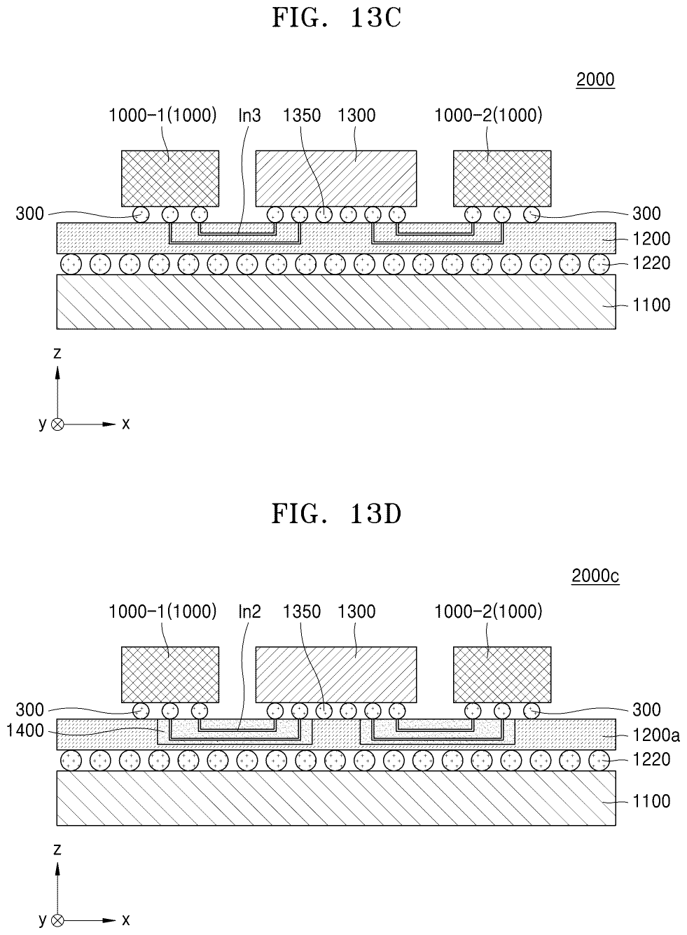

FIGS. 13A to 13D are cross-sectional views of a system package according to some embodiments. The descriptions already given with reference to FIGS. 1 to 12B are briefly given or omitted. For reference, FIGS. 13A to 13D are cross-sectional views corresponding to FIG. 12B, and schematically illustrate only the semiconductor package 1000, the package substrate 1100 or interposer 1200, and the semiconductor device 1300 in terms of the connection structure between the semiconductor package 1000 and the semiconductor device 1300, without a first connection terminal and an external sealing material.

Referring to FIG. 13A, a system package 2000a of the present embodiment may include the semiconductor package 1000, the package substrate 1100, and the semiconductor device 1300. The system package 2000a of the present embodiment may not include an interposer compared to the system package 2000 of FIG. 12B. Accordingly, the semiconductor package 1000 may be directly mounted on the package substrate 1100 through the external connection terminal 300. In addition, the semiconductor device 1300 may be directly mounted on the package substrate 1100 through the third connection terminal 1350. Detailed structures or functions of the package substrate 1100, the semiconductor package 1000, and the semiconductor device 1300 are the same as those described with respect to the system package 2000 of FIG. 12B. As shown in FIG. 13A, in the system package 2000a of the present embodiment, the semiconductor package 1000 and the semiconductor device 1300 may be connected to each other through a first connection wiring In1 of the package substrate 1100. The first connection wiring In1 may be one of wiring lines of the package substrate 1100.

Referring to FIG. 13B, a system package 2000b of the present embodiment may include the semiconductor package 1000, a package substrate 1100a, the semiconductor device 1300, and a Si-bridge 1400. The system package 2000b of the present embodiment may further include the Si-bridge 1400 compared to the system package 2000a of FIG. 13A.

As shown in FIG. 13B, the Si-bridge 1400 may be disposed in the package substrate 1100a. The Si-bridge 1400 may be disposed inside the package substrate 1100a at a position corresponding between the semiconductor package 1000 and the semiconductor device 1300. In addition, the Si-bridge 1400 may overlap a part of the semiconductor package 1000 and a part of the semiconductor device 1300. In the system package 2000b of the present embodiment, the semiconductor package 1000 may be disposed on both sides of the semiconductor device 1300 in an x-direction. Accordingly, the Si-bridge 1400 may be disposed on both sides of the semiconductor device 1300 in the x-direction.

The Si-bridge 1400 may include a second connection wiring In2 therein. The Si-bridge 1400 may connect the semiconductor package 1000 and the semiconductor device 1300 to each other through the second connection wiring In2. Consequently, in the system package 2000b of the present embodiment, the semiconductor package 1000 and the semiconductor device 1300 may be connected to each other by using the Si-bridge 1400 separately disposed in the package substrate 1100a.

Referring to FIG. 13C, the system package 2000 of the present embodiment may be substantially the same as the system package 2000 of FIG. 12B. Accordingly, the system package 2000 of the present embodiment may include the semiconductor package 1000, the package substrate 1100, the interposer 1200, and the semiconductor device 1300. The semiconductor package 1000 may be mounted on the interposer 1200 through the external connection terminal 300, and the semiconductor device 1300 may be mounted on the interposer 1200 through the third connection terminal 1350. As shown in FIG. 13C, in the system package 2000 of the present embodiment, the semiconductor package 1000 and the semiconductor device 1300 may be connected to each other through a third connection wiring In3 of the interposer 1200. Meanwhile, the third connection wiring In3 may include a wiring line of the wiring layer 1210 and the through electrode 1220, or may include only the wiring line of the wiring layer 1210.

Referring to FIG. 13D, a system package 2000c of the present embodiment may include the semiconductor package 1000, the package substrate 1100, an interposer 1200a, the semiconductor device 1300, and the Si-bridge 1400. The system package 2000c of the present embodiment may further include the Si-bridge 1400 compared to the system package 2000 of FIG. 13c.

As shown in FIG. 13D, the Si-bridge 1400 may be disposed in the interposer 1200a. The Si-bridge 1400 may be disposed inside the interposer 1200a at a position corresponding between the semiconductor package 1000 and the semiconductor device 1300. In addition, the Si-bridge 1400 may overlap a part of the semiconductor package 1000 and a part of the semiconductor device 1300. In the system package 2000c of the present embodiment, the semiconductor package 1000 may be disposed on both sides of the semiconductor device 1300 in the x-direction. Accordingly, the Si-bridge 1400 may be disposed on both sides of the semiconductor device 1300 in the x-direction.

The Si-bridge 1400 may include the second connection wiring In2 therein. The Si-bridge 1400 may connect the semiconductor package 1000 and the semiconductor device 1300 to each other through the second connection wiring In2. Consequently, in the system package 2000c of the present embodiment, the semiconductor package 1000 and the semiconductor device 1300 may be connected to each other by using the Si-bridge 1400 separately disposed in the interposer 1200a.

While the inventive concept has been particularly shown and described with reference to embodiments thereof, it will be understood that various changes in form and details may be made therein without departing from the spirit and scope of the following claims.

1. A semiconductor package comprising:
a base chip;
a plurality of memory chips on the base chip and including a first memory chip disposed lowermost among the plurality of memory chips; and
a bonding metal on a first outer portion of a top surface of the base chip and a second outer portion of a bottom surface of the first memory chip;
wherein the bonding metal is formed by coupling a first metal pattern on the first outer portion to a second metal pattern on the second outer portion.

2. The semiconductor package of claim 1, wherein:
the top surface of the base chip and the bottom surface of the first memory chip each have a shape of a rectangle; and
each of the first metal pattern and the second metal pattern has a shape of a rectangular ring extending along four sides of the rectangle.

3. The semiconductor package of claim 1, wherein:
the top surface of the base chip and the bottom surface of the first memory chip each have a shape of a rectangle; and
each of the first metal pattern and the second metal pattern is disposed adjacent to four vertices of the rectangle.

4. The semiconductor package of claim 3, wherein each of the first metal pattern and the second metal pattern has a shape of a triangle, a square, or a fan.

5. The semiconductor package of claim 1, wherein:
the top surface of the base chip and the bottom surface of the first memory chip each have a shape of a rectangle; and
each of the first metal pattern and the second metal pattern includes a first portion having a shape of a rectangular ring extending along four sides of the rectangle and a second portion disposed adjacent to four vertices of the rectangle.

6. The semiconductor package of claim 1, wherein:
the top surface of the base chip and the bottom surface of the first memory chip each have a shape of a rectangle;
the base chip is larger than the first memory chip;
the second metal pattern is disposed on four sides of the rectangle, four vertices of the rectangle, or the four sides and the four vertices; and
the first metal pattern is disposed at a position corresponding to the second metal pattern.

7. The semiconductor package of claim 6, wherein the first metal pattern is spaced apart from the four sides and the four vertices of the rectangle and is disposed at the position corresponding to the second metal pattern, or extends from the position corresponding to the second metal pattern to the four sides and the four vertices of the rectangle.

8. The semiconductor package of claim 1, further including an upper bonding metal formed by coupling a third metal pattern on an outer portion of a lower memory chip among two adjacent memory chips of the plurality of memory chips to a fourth metal pattern on a bottom surface of an upper memory chip among the two adjacent memory chips.

9. The semiconductor package of claim 1, wherein no connection terminals are disposed between the base chip and the first memory chip and between the memory chips adjacent to each other.

10. The semiconductor package of claim 1, wherein:
the semiconductor package is a high bandwidth memory (HBM) package;
the base chip includes a buffer chip; and
each of the plurality of memory chips includes a dynamic random access memory (DRAM) chip.

11. A semiconductor package comprising:
a base chip;
a first memory chip stacked on the base chip through hybrid copper bonding (HCB);
a plurality of second memory chips stacked on the first memory chip through HCB; and
a bonding metal on a first outer portion of a top surface of the base chip and a second outer portion of a bottom surface of the first memory chip;
wherein the bonding metal is formed by coupling a first metal pattern on the first outer portion to a second metal pattern on the second outer portion;
the top surface of the base chip and the bottom surface of the first memory chip each have a shape of a rectangle;
the first metal pattern is disposed at four sides of the rectangle, four vertices of the rectangle, or the four sides and the four vertices of the rectangle; and
the second metal pattern is disposed at a position corresponding to the first metal pattern.

12. The semiconductor package of claim 11, wherein each of the first metal pattern and the second metal pattern has a shape of a rectangular ring extending along four sides of the rectangle.

13. The semiconductor package of claim 11, wherein each of the first metal pattern and the second metal pattern is disposed adjacent to four vertices of the rectangle and has a shape of a triangle, a square, or a fan.

14. The semiconductor package of claim 11, wherein each of the first metal pattern and the second metal pattern includes a first portion having a shape of a rectangular ring extending along four sides of the rectangle and a second portion disposed adjacent to four vertices of the rectangle.

15. The semiconductor package of claim 11, wherein:
the base chip is larger than the first memory chip;
the second metal pattern is disposed on the four sides of the rectangle or the four vertices of the rectangle; and
the first metal pattern is spaced apart from the four sides and the four vertices of the rectangle and is disposed at the position corresponding to the second metal pattern, or extends from the position corresponding to the second metal pattern to the four sides and the four vertices of the rectangle.

16. A semiconductor package comprising:
a package substrate;
a first semiconductor device on the package substrate; and
at least one second semiconductor device on the package substrate adjacent to the first semiconductor device;
wherein the at least one second semiconductor device has a package structure including:
a base chip;
a plurality of memory chips on the base chip and
a bonding metal on a first outer portion of a top surface of the base chip and a second outer portion of a bottom surface of a first memory chip disposed lowermost among the plurality of memory chips; and
the bonding metal is formed by coupling a first metal pattern on the first outer portion to a second metal pattern on the second outer portion.

17. The semiconductor package of claim 16, wherein:
the top surface of the base chip and the bottom surface of the first memory chip each have a shape of a rectangle; and
each of the first metal pattern and the second metal pattern includes any one of:
a first structure having a shape of a rectangular ring extending along four sides of the rectangle;
a second structure disposed adjacent to four vertices of the rectangle and having a shape of a triangle, a square, or a fan shape; and
a third structure including a first portion having a shape of a rectangular ring extending along four sides of the rectangle and a second portion disposed adjacent to four vertices of the rectangle.

18. The semiconductor package of claim 16, wherein:
the top surface of the base chip and the bottom surface of the first memory chip each have a shape of a rectangle;
the base chip is larger than the first memory chip;
the second metal pattern is disposed on four sides of the rectangle or four vertices of the rectangle; and
the first metal pattern is spaced apart from the four sides and the four vertices of the rectangle and is disposed at the position corresponding to the second metal pattern, or extends from the position corresponding to the second metal pattern to the four sides and the four vertices of the rectangle.

19. The semiconductor package of claim 16, wherein:
the first semiconductor device includes a logic chip; and
the second semiconductor device includes a high bandwidth memory (HBM) package.

20. The semiconductor package of claim 16, further including an intermediate substrate disposed on the package substrate or a silicon-bridge disposed in the package substrate,
wherein the first semiconductor device and the second semiconductor device are connected to each other through the intermediate substrate or the silicon-bridge.

21.-25. (canceled)
